(19) United States
(12) Patent Application Publication
(10) Pub. No.: US 2020/0161488 A1
(43) Pub. Date: May 21, 2020

(54) PHOTOELECTRIC CONVERSION DEVICE, PHOTOELECTRIC CONVERSION MODULE, ELECTRONIC APPARATUS, AND METHOD OF MANUFACTURING PHOTOELECTRIC CONVERSION DEVICE

(71) Applicant: SEIKO EPSON CORPORATION, Tokyo (JP)

(72) Inventor: Takuya KINUGAWA, Suwa-shi (JP)

(73) Assignee: SEIKO EPSON CORPORATION, Tokyo (JP)

(21) Appl. No.: 16/689,971

(22) Filed: Nov. 20, 2019

(30) Foreign Application Priority Data
Nov. 21, 2018 (JP) 2018-217999

(51) Int. Cl. H01L 31/0445; G04C 10/02; H01L 31/054; H01L 31/18

(52) U.S. Cl. CPC H01L 31/0445; H01L 31/1804; H01L 31/054; G04C 10/02

(57) ABSTRACT

The photoelectric conversion device includes a semiconductor substrate including silicon, a first photoelectric conversion area and a second photoelectric conversion area which are disposed in the semiconductor substrate, and receive light to perform a photoelectric conversion, and a first insulating area sandwiched between the first photoelectric conversion area and the second photoelectric conversion area, and including a second insulating film made of an Si oxide.

The present application is based on, and claims priority from JP Application Serial Number 2018-217999, filed Nov. 21, 2018, the disclosure of which is hereby incorporated by reference herein in its entirety.

### BACKGROUND

### 1. Technical Field

The present disclosure relates to a photoelectric conversion device, a photoelectric conversion module, an electronic apparatus, and a method of manufacturing a photoelectric conversion device.

### 2. Related Art

A photoelectric conversion device is widely utilized for a portable electronic apparatus such as a wristwatch. The photoelectric conversion device is a device for converting the energy of the light received into electrical energy, and is called a photovoltaic device, a solar panel, a solar cell module, and so on. The photoelectric conversion device has a structure in which a plurality of diodes is arranged in a silicon substrate.

In the photoelectric conversion device, an n+ layer and a p+ layer are arranged in the substrate. Further, when the substrate is irradiated with light, the free electrons are excited and carried to the n+ layer. Further, the free holes are excited and carried to the p+ layer. A negative electrode is coupled to the n+ layer. A positive electrode is coupled to the p+ layer. Further, when an electrical load is coupled between the electrodes, an electrical current flows through the electrical load. Therefore, the photoelectric conversion device functions as a power-generating device.

When the voltage between positive electrode and negative electrode is lower than a voltage desired to be output, it is possible to raise the voltage by connecting the positive electrodes and the negative electrodes in series. When the current flowing between positive electrode and negative electrode is smaller than a current desired to be output, it is possible to increase the current by connecting the positive electrodes and the negative electrodes in parallel.

In JP-A-2016-167588 (Document 1), there is disclosed a solar cell module as the photoelectric conversion device having the solar cells as a plurality of photoelectric conversion areas arranged. According to the document, the photoelectric conversion areas are arranged in a matrix. Each of the photoelectric conversion areas is electrically isolated. Further, in each of the photoelectric conversion areas, the electrodes can be connected in series or in parallel. A sealing member is disposed so as cover the photoelectric conversion areas. Further, on the surface of the sealing member, there is disposed a surface side protective member. Irradiated light on an area between the photoelectric conversion areas adjacent to each other does not make a contribution to power generation. Therefore, between the photoelectric conversion areas adjacent to each other, there is disposed a light diffusion sheet for diffusing the light with which the light diffusion sheet is irradiated. Further, the light diffused by the light diffusion sheet passes through the sealing member to reach the photoelectric conversion area to make a contribution to the power generation.

When disposing the light diffusion sheet as in Document 1, since the light diffusion sheet covers a part of the photoelectric conversion area, the area of the photoelectric conversion area decreases. Therefore, there is required the photoelectric conversion device capable of increasing the area of the photoelectric conversion area.

### SUMMARY

A photoelectric conversion device according to an aspect of the present disclosure includes a semiconductor substrate including silicon, wherein the semiconductor substrate includes a first photoelectric conversion area and a second photoelectric conversion area which are disposed in the semiconductor substrate, and receive light to perform a photoelectric conversion, and an insulating area which is disposed between the first photoelectric conversion area and the second photoelectric conversion area, and includes an Si oxide.

In the photoelectric conversion device described above, the insulating area may include an Si nitride surrounded by the Si oxide.

In the photoelectric conversion device described above, the width of the Si oxide may be no smaller than 1 μm and no larger than 5 μm.

In the photoelectric conversion device described above, a first impurity area of a first conductivity type and a second impurity area of a second conductivity type different from the first impurity area disposed in the first photoelectric conversion area and the second photoelectric conversion area, and an interconnection configured to electrically couple the first impurity area disposed in the first photoelectric conversion area and the second impurity area disposed in the second photoelectric conversion area to each other may be provided to a second surface at an opposite side to a first surface with which the semiconductor substrate receives the light, and the interconnection may be disposed so as to pass above the insulating area.

A photoelectric conversion module according to an aspect of the present disclosure includes the photoelectric conversion device described above, and a wiring board electrically coupled to the photoelectric conversion device.

An electronic apparatus according to an aspect of the present disclosure includes the photoelectric conversion module described above.

A method of manufacturing the photoelectric conversion device according to an aspect of the present disclosure includes the steps of forming recessed parts arranged at predetermined intervals from a second surface of a semiconductor substrate at an opposite side to a first surface of the semiconductor substrate on which light is incident, the semiconductor substrate including silicon, forming an insulating area including an Si oxide in a shape having circular rings connected to each other in a row by thermally oxidizing silicon in the recessed parts, forming a first impurity area of a first conductivity type and a second impurity area of a second conductivity type different from the first impurity area in each of a first photoelectric conversion area and a second photoelectric conversion area located across the insulating area, disposing an interconnection configured to electrically couple the first impurity area disposed in the first photoelectric conversion area and the second impurity area disposed in the second photoelectric conversion area to each other so as to pass above the insulating area, and grinding the first surface of the semiconductor substrate to expose the Si oxide.

### BRIEF DESCRIPTION OF THE DRAWINGS

FIG. 1 is a schematic plan view showing a configuration of a wristwatch according to a first embodiment.

FIG. 2 is a schematic side cross-sectional view showing an internal structure of the wristwatch.

FIG. 3 is a schematic plan view showing a configuration of a photoelectric conversion module.

FIG. 4 is a schematic side cross-sectional view showing a configuration of a photoelectric conversion device.

FIG. 5 is a schematic plan view of a principal part showing a structure of a positive electrode and a negative electrode.

FIG. 6 is a schematic plan view for explaining an insulating area.

FIG. 7 is a schematic side cross-sectional view for explaining the insulating area.

FIG. 8 is a schematic plan view of a principal part for explaining a coupling interconnection.

FIG. 9 is a schematic plan view of a principal part for explaining a wiring board.

FIG. 10 is a schematic side cross-sectional view of a principal part for explaining the wiring board.

FIG. 11 is a flowchart of a method of manufacturing the photoelectric conversion module.

FIG. 12 is a schematic diagram for explaining the method of manufacturing the photoelectric conversion module.

FIG. 13 is a schematic diagram for explaining the method of manufacturing the photoelectric conversion module.

FIG. 14 is a schematic diagram for explaining the method of manufacturing the photoelectric conversion module.

FIG. 15 is a schematic diagram for explaining the method of manufacturing the photoelectric conversion module.

FIG. 16 is a schematic diagram for explaining the method of manufacturing the photoelectric conversion module.

FIG. 17 is a schematic diagram for explaining the method of manufacturing the photoelectric conversion module.

FIG. 18 is a schematic diagram for explaining the method of manufacturing the photoelectric conversion module.

FIG. 19 is a schematic diagram for explaining the method of manufacturing the photoelectric conversion module.

FIG. 20 is a schematic diagram for explaining the method of manufacturing the photoelectric conversion module.

FIG. 21 is a schematic diagram for explaining the method of manufacturing the photoelectric conversion module.

FIG. 22 is a schematic diagram for explaining the method of manufacturing the photoelectric conversion module.

FIG. 23 is a schematic diagram for explaining the method of manufacturing the photoelectric conversion module.

FIG. 24 is a schematic diagram for explaining the method of manufacturing the photoelectric conversion module.

FIG. 25 is a schematic diagram for explaining the method of manufacturing the photoelectric conversion module.

FIG. 26 is a schematic diagram for explaining the method of manufacturing the photoelectric conversion module.

FIG. 27 is a schematic plan view for explaining an insulating area related to a second embodiment.

FIG. 28 is a schematic side cross-sectional view for explaining the insulating area.

FIG. 29 is a schematic side cross-sectional view for explaining the insulating area.

FIG. 30 is a schematic plan view for explaining an insulating area related to a third embodiment.

FIG. 31 is a schematic side cross-sectional view for explaining the insulating area.

FIG. 32 is a schematic side cross-sectional view for explaining the insulating area.

### DESCRIPTION OF EXEMPLARY EMBODIMENTS

Hereinafter, an embodiment will be described along the accompanying drawings. It should be noted that each of the members in each of the drawings is illustrated with a different scale from each other in order to provide a size large enough to be recognized in the drawing.

### First Embodiment

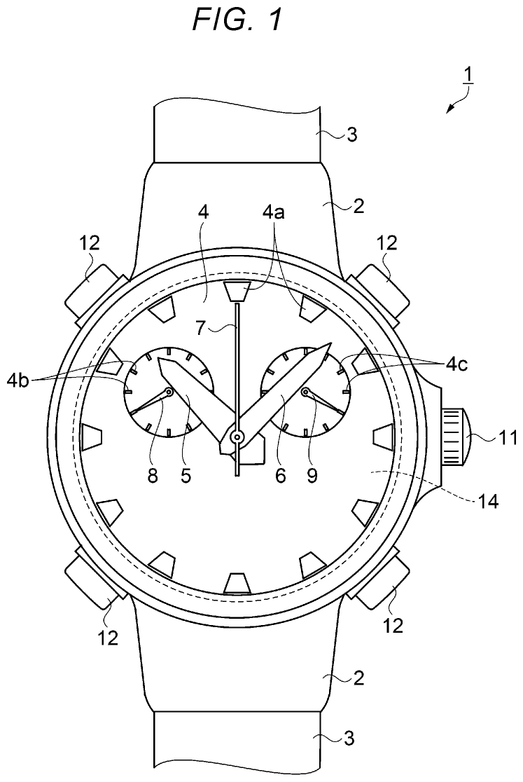

In the present embodiment, a characteristic example of a wristwatch and a photoelectric conversion device installed in the wristwatch is described along the accompanying drawings. The wristwatch and the photoelectric conversion device according to the first embodiment is described along FIG. 1 through FIG. 10. FIG. 1 is a schematic plan view showing a configuration of the wristwatch. As shown in FIG. 1, a wristwatch 1 as the electronic apparatus is provided with a case 2. A band 3 is disposed on the upper side and the lower side in the drawing of the case 2. The case 2 and the bands 3 form a ring. By inserting an arm through the ring to mount the ring on the arm, and then adjusting the size of the ring, the wristwatch 1 is fixed to the arm.

In the center of the drawing, a dial 4 having a disk-like shape is disposed inside the case 2. On the dial 4, there is concentrically disposed a first scale 4a. At the center of the dial 4, there are disposed an hour hand 5 and a minute hand 6 for indicating time. The wristwatch 1 is provided with a stopwatch function, and at the center of the dial, there is disposed a timing second hand 7.

On the upper left side in the drawing of the dial 4, there is disposed a time-displaying second hand 8. On the periphery of the time-displaying second hand 8, there is concentrically disposed a second scale 4b as a scale for the time-displaying second hand 8. The time-displaying second hand 8 represents second in the current time.

On the upper right side in the drawing of the dial 4, there is disposed a first displaying hand 9. On the periphery of the first displaying hand 9, there is concentrically disposed a third scale 4c as a scale for the first displaying hand 9. The wristwatch 1 is provided with a direction sensor inside. Further, the first displaying hand 9 is used when indicating the northern direction.

On the right side in the drawing of the case 2, there is disposed a winder 11. The winder 11 is used when adjusting the time indicated by the hour hand 5 and the minute hand 6. It is possible for the operator to rotate the hour hand 5 and the minute hand 6 by pulling out and then rotating the winder 11.

Operation buttons 12 are respectively disposed on the upper right side, the lower right side, the upper left side, and the lower left side in the drawing of the case 2. It is possible for the operator to make the wristwatch 1 perform a variety of functions by operating the operation buttons 12. For example, when making the wristwatch 1 perform a stopwatch function, the operator operates the operation buttons 12 to make the wristwatch 1 perform start, stop, reset, and so on. Besides the above, the operator operates the operation buttons 12 to make the first displaying hand 9 indicate the northern direction.

The case 2 and the bands 3 are formed of a material having rigidity such as stainless steel or titanium. The winder 11, the operation buttons 12, the first scale 4a, the second scale 4b, and the third scale 4c are formed of a material having rigidity and easy to process such as a copper alloy or an iron alloy. The dial 4 is formed of a light transmissive material such as resin or ceramics.

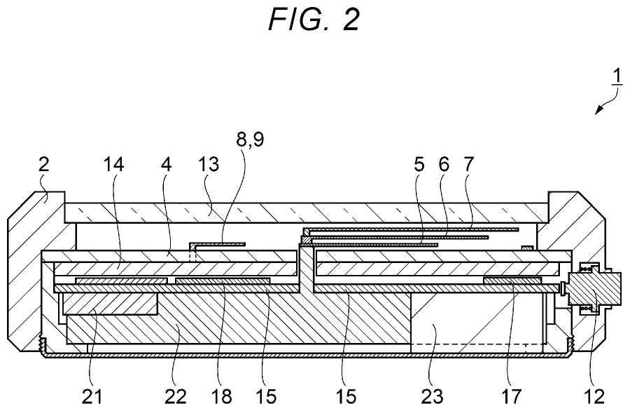

FIG. 2 is a schematic side cross-sectional view showing an internal structure of the wristwatch. As shown in FIG. 2, on the upper side in the drawing of the wristwatch 1, a windshield plate 13 is fixed to the case 2. The windshield plate 13 is formed of a material having a light transmissive property such as glass. On the lower side in the drawing of the windshield plate 13, there is disposed the dial 4. Further, between the dial 4 and the windshield plate 13, there are disposed the hour hand 5, the minute hand 6, the timing second hand 7, the time-displaying second hand 8, and the first displaying hand 9. It is possible for the operator to see the hour hand 5, the minute hand 6, the timing second hand 7, the time-displaying second hand 8, the first displaying hand 9, and the dial 4 through the windshield plate 13.

On the lower side in the drawing of the dial 4, there is disposed a photoelectric conversion module 14. The photoelectric conversion module 14 receives indoor light or the solar light to generate power. Since the dial 4 transmits light, the light irradiates the dial 4 is transmitted through the dial 4, and thus, the photoelectric conversion module 14 is irradiated with the light.

On the lower side in the drawing of the photoelectric conversion module 14, there is disposed a circuit board 15. On the surface at the upper side in the drawing of the circuit board 15, there are disposed a variety of electric elements such as a memory besides a direction sensor 17 and a CPU 18 (central processing unit).

The direction sensor 17 is a sensor for detecting the geomagnetism. The geomagnetism received by the wristwatch 1 varies in accordance with a place where the operator exists. The direction sensor 17 detects the direction of the geomagnetism received by the wristwatch 1. Then, the CPU 18 assumes the northern direction from the geomagnetism received by the wristwatch 1 to make the first displaying hand 9 indicate the northern direction.

On the lower side in the drawing of the circuit board 15, there is disposed a GPS (global positioning system) antenna 21. The GPS antenna 21 receives radio waves from position information satellites. Then, the CPU 18 obtains the time included in a positioning signal to correct the time display represented by the hour hand 5, the minute hand 6, and the timing second hand 7.

On the lower side in the drawing of the circuit board 15, there are disposed a movement 22 and a secondary cell 23. In the movement 22, there are disposed a plurality of motors and gear trains. Further, the CPU 18 controls the movement 22. At the center in the drawing, a part of the movement 22 protrudes toward the upper side in the drawing and penetrates the dial 4. Further, in the movement 22 in the protruding part, there are disposed the hour hand 5, the minute hand 6, the timing second hand 7, the time-displaying second hand 8, and the first displaying hand 9. Further, the CPU 18 makes the movement 22 rotate the hour hand 5, the minute hand 6, the timing second hand 7, the time-displaying second hand 8, and the first displaying hand 9 to control the position in the scale indicated by each of the hands.

The secondary cell 23 is charged by the power generated by photoelectric conversion module 14. Further, the electrical energy charged in the secondary cell 23 is used for the direction sensor 17, the circuit board 15, the motor of the movement 22, and so on. The wristwatch 1 is provided with the direction sensor 17 and the GPS antenna 21, and is therefore made to be a timepiece high in power consumption compared to a timepiece provided only with a function of displaying the current time. Therefore, the photoelectric conversion module 14 is required to have a function of efficiently generating power. The photoelectric conversion module denotes, for example, a solar cell module.

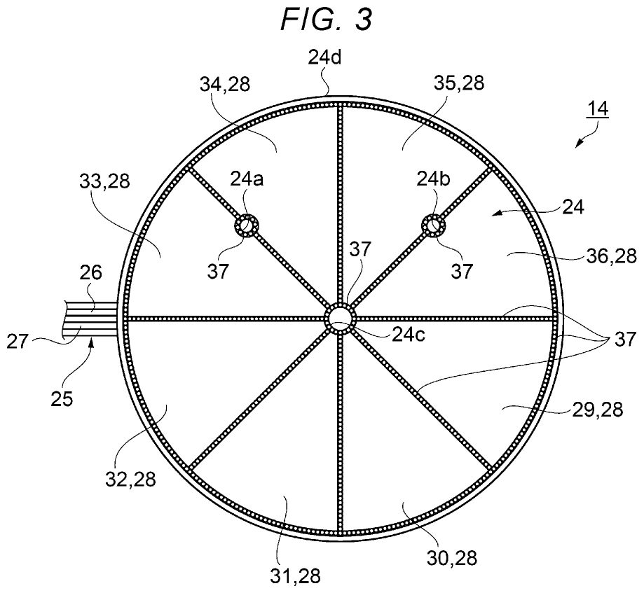

FIG. 3 is a schematic plan view showing a configuration of the photoelectric conversion module, and is a diagram of the photoelectric conversion module 14 viewed from the dial 4 side. As shown in FIG. 3, the photoelectric conversion module 14 is provided with a photoelectric conversion device 24 and a wiring board 25. Therefore, the wristwatch 1 is provided with the photoelectric conversion device 24. Further, the wiring board 25 is disposed so as to overlap a part of the photoelectric conversion device 24. Further, the photoelectric conversion device 24 and the wiring board 25 are electrically coupled to each other. The wiring board 25 has a substantially rectangular shape, and has a shape elongated in the horizontal direction in the drawing. The wiring board 25 is coupled to the secondary cell 23. In detail, the wiring board 25 is provided with a first board interconnection 26 and a second board interconnection 27, and the first board interconnection 26 and the second board interconnection 27 are electrically coupled to the photoelectric conversion device 24 and the secondary cell 23 to charge the secondary cell 23 with electrical energy generated in the photoelectric conversion device 24. The photoelectric conversion device is, for example, a solar cell.

The photoelectric conversion device 24 has a circular shape. The single photoelectric conversion device 24 is provided with 8 photoelectric conversion areas 28. The photoelectric conversion areas 28 each have a shape obtained by dividing the area of a disk into eight substantially equal parts. The photoelectric conversion area 28 located on the lower right side in the drawing corresponds to a first photoelectric conversion area 29. In the photoelectric conversion device 24, there are arranged a second photoelectric conversion area 30, a third photoelectric conversion area 31, a fourth photoelectric conversion area 32, a fifth photoelectric conversion area 33, a sixth photoelectric conversion area 34, a seventh photoelectric conversion area 35, and an eighth photoelectric conversion area 36 clockwise in the drawing started from the first photoelectric conversion area 29. The eight photoelectric conversion areas 28 including the first photoelectric conversion area 29 and the second photoelectric conversion area 30 each receive light to perform a photoelectric conversion. The photoelectric conversion areas each correspond to a so-called solar cell.

Further, the photoelectric conversion areas 28, namely the first photoelectric conversion area 29 through the eighth photoelectric conversion area 36, constitute the photoelectric conversion device 24 having a circular shape. In other words, the first photoelectric conversion area 29 through the eighth photoelectric conversion area 36 each have a shape obtained by dividing a disk into eight equal parts. The first photoelectric conversion areas 29 through the eighth photoelectric conversion area 36 each have the same structure. The shape of each of the photoelectric conversion areas 28 is not limited to this shape. A shape obtained by dividing one circle into two or three parts can be adopted, and a shape obtained by dividing one circle into five or more parts can also be adopted. Further, the shape of each of the photoelectric conversion areas 28 is not limited to a sector shape, but it is also possible to adopt a shape constituted by curved lines or straight lines besides a polygonal shape or an elliptical shape. Between the fifth photoelectric conversion area 33 and the sixth photoelectric conversion area 34, there is disposed a hole 24a for disposing the time-displaying second hand 8. Between the seventh photoelectric conversion area 35 and the eighth photoelectric conversion area 36, there is disposed a hole 24b for disposing the first displaying hand 9. At the center in the drawing of the photoelectric conversion device 24, there is disposed a hole 24c for disposing the hour hand 5, the minute hand 6, and the timing second hand 7.

Between the photoelectric conversion areas 28 adjacent to each other, there is disposed a first insulating area 37 as an insulating area. The first insulating area 37 is also disposed on the peripheries of the hole 24a, the hole 24b, and the hole 24c. The first insulating area 37 is further disposed along an outer circumference 24b of the photoelectric conversion device 24. As described above, the first insulating area 37 is disposed so as to surround each of the photoelectric conversion areas 28. Further, a part of the first insulating area 37 is disposed between the first photoelectric conversion area 29 and the second photoelectric conversion area 30.

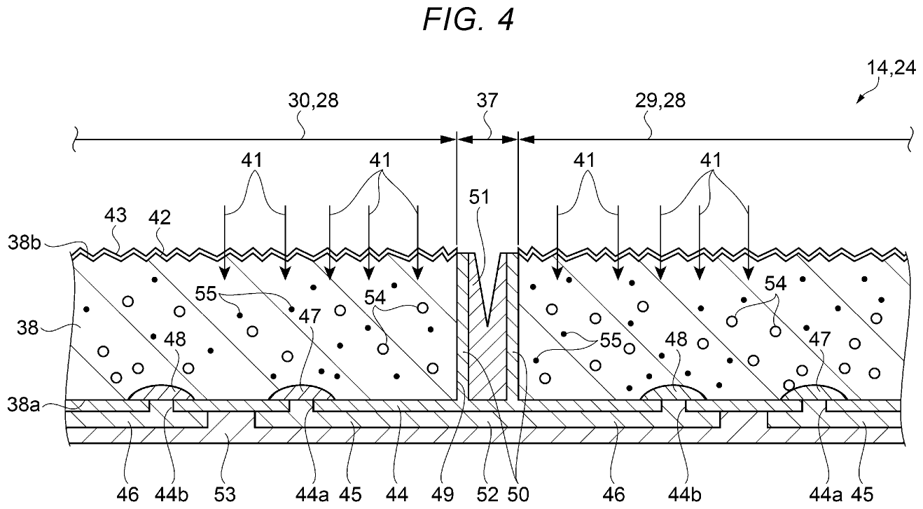

FIG. 4 is a schematic side cross-sectional view showing a configuration of the photoelectric conversion device. As shown in FIG. 4, the photoelectric conversion device 24 is provided with a semiconductor substrate 38. The semiconductor substrate 38 is a substrate including silicon. The semiconductor substrate 38 can be made of amorphous silicon, or can also be made of single-crystal silicon, or can also include amorphous silicon and single-crystal silicon. In the present embodiment, for example, the semiconductor substrate 38 is formed of single-crystal silicon in the photoelectric conversion device 24.

In the semiconductor substrate 38, the surface at the side on which the wiring board 25 is disposed is defined as a second surface 38a. In the semiconductor substrate 38, the surface at the opposite side to the second surface 38a is defined as a first surface 38b. The first surface 38b is a surface irradiated with light 41.

The first surface 38b of the semiconductor substrate 38 can be provided with a texture 42 having a concavo-convex shape. The texture 42 is constituted by, for example, a number of substantially pyramidal protrusions. By disposing such a texture 42 to cause multiple reflection of light, it is possible to suppress a reflection loss of external light in the first surface 38b to achieve an increase in an amount of light entering the semiconductor substrate 38. When the semiconductor substrate 38 is, for example, a substrate having the (100) plane as a principal surface, pyramidal protrusions each having the (111) plane as a tilted surface are preferably used as the texture 42.

Further, in the semiconductor substrate 38, an antireflection film 43 is formed on the surface provided with the texture 42. The antireflection film 43 has a function of preventing reflection of light, and a function of a protective film. As a constituent material of the antireflection film 43, there can be cited, for example, silicon oxide, silicon nitride, silicon oxynitride, and aluminum oxide. Silicon oxide is also called an Si oxide. Silicon nitride is also called an Si nitride. In the present embodiment, for example, an Si oxide is used as the constituent material of the antireflection film 43.

In the semiconductor substrate 38, there are disposed the first photoelectric conversion area 29 and the second photoelectric conversion area 30. Further, in the semiconductor substrate 38, there are disposed the third photoelectric conversion area 31 through the eighth photoelectric conversion area 36.

On the second surface 38a of the semiconductor substrate 38, there is disposed a first insulating film 44. The first insulating film 44 can be a silicon dioxide film, or can also be a silicon nitride film, but in the present embodiment, there is adopted, for example, the silicon dioxide film.

In the first insulating area 37 of each of the first photoelectric conversion area 29 through the eighth photoelectric conversion area 36, a positive electrode 45 as an interconnection and a negative electrode 46 as an interconnection are arranged side by side in the second surface 38a so as to be stacked on the first insulating film 44. The first insulating film 44 located in an area opposed to the positive electrode 45 is provided with a first hole 44a disposed in a predetermined place. Further, in the first hole 44a, the positive electrode 45 has contact with the semiconductor substrate 38. In the area where the first hole 44a is disposed, the semiconductor substrate 38 located on the second surface 38a side is provided with a p+ impurity area 47 as a second impurity area of a second conductivity type. The p+ impurity area 47 is an area which forms a p+ type semiconductor by an element of the group III such as boron being injected in the semiconductor substrate 38. The second conductivity type is set to the p+ type.

The first insulating film 44 located in an area opposed to the negative electrode 46 is provided with a second hole 44b disposed in a predetermined place. Further, in the second hole 44b, the negative electrode 46 has contact with the semiconductor substrate 38. In the area where the second hole 44b is disposed, the semiconductor substrate 38 located on the second surface 38a side is provided with an n+ impurity area 48 as a first impurity area of a first conductivity type. The n+ impurity area 48 is an area which forms an n+ type semiconductor by an element of the group V such as phosphorus or arsenic being injected in the semiconductor substrate 38. The first conductivity type is set to the n+ type.

The semiconductor substrate 38 is provided with the p+ impurity area 47 disposed in an area opposed to the positive electrode 45. The p+ impurity areas 47 are arranged along the positive electrode 45. Similarly, the semiconductor substrate 38 is provided with the n+ impurity area 48 disposed in an area opposed to the negative electrode 46. The n+ impurity areas 48 are arranged along the negative electrode 46. Further, the p+ impurity area 47 and the n+ impurity area 48 are arranged at a distance to form a diode.

As described above, on the second surface 38a on the opposite side to the first surface 38b with which the semiconductor substrate 38 receives the light 41, there are disposed the p+ impurity areas 47 and the n+ impurity areas 48 different from the p+ impurity areas 47 in the first photoelectric conversion area 29 and the second photoelectric conversion area 30. Further, on the second surface 38a of the semiconductor substrate 38, there are disposed the positive electrodes 45 and the negative electrodes 46. The positive electrode 45 is electrically coupled to the p+ impurity area 47. The negative electrode 46 is electrically coupled to the n+ impurity area 48. The negative electrode 46 is an electrode different in polarity from the positive electrode 45.

The first insulating area 37 is provided with third holes 49 arranged in a row. The axial direction of the third holes 49 is set to the thickness direction of the semiconductor substrate 38. On the side surface of the third hole 49, there is disposed a second insulating film 50 as a circular ring and the Si oxide. Further, the material of the second insulating film 50 includes the Si oxide. Therefore, the first insulating area 37 includes the Si oxide. Further, the shape of the Si oxide when viewed from the thickness direction of the semiconductor substrate 38 in the first insulating area 37 is a shape having circular rings arranged in a row. Here, the thickness direction of the semiconductor substrate 38 denotes a normal direction of the second surface 38a and the first surface 38b, and viewing from the thickness direction of the semiconductor substrate 38 denotes viewing from the direction of the plan of the second surface 38a or the first surface 38b.

Inside the second insulating film 50, there is disposed a first reinforcing part 51 as an Si nitride. The first insulating area 37 is reinforced by the first reinforcing part 51. Further, the first reinforcing part 51 prevents the first photoelectric conversion area 29 and the second photoelectric conversion area 30 from being folded in the first insulating area 37. The material of the first reinforcing part 51 is not particularly limited as long as the material is good in workability, and sufficient strength can be obtained. As the material of the first reinforcing part 51, there is used an Si compound such as an Si oxide or an Si nitride. At the center of the second insulating film 50, there is disposed the Si compound. In the present embodiment, for example, an Si nitride is used as the material of the first reinforcing part 51. Therefore, the first insulating area 37 has the Si nitride surrounded by an Si oxide.

In the first insulating area 37 on the second surface 38a, there is disposed a coupling interconnection 52 as an interconnection. The coupling interconnection 52 is an interconnection for coupling the positive electrode 45 and the negative electrode 46 in the respective photoelectric conversion areas 28 adjacent to each other. For example, the coupling interconnection 52 electrically couples the negative electrode 46 located in the first photoelectric conversion area 29 and the positive electrode 45 located in the second photoelectric conversion area 30 to each other. Besides the above, the coupling interconnection 52 electrically couples the negative electrode 46 located in the second photoelectric conversion area 30 and the positive electrode 45 located in the third photoelectric conversion area 31 to each other.

Besides the above, the coupling interconnection 52 electrically couples the negative electrode 46 located in the third photoelectric conversion area 31 and the positive electrode 45 located in the fourth photoelectric conversion area 32 to each other. Besides the above, the coupling interconnection 52 electrically couples the negative electrode 46 located in the fifth photoelectric conversion area 33 and the positive electrode 45 located in the sixth photoelectric conversion area 34 to each other. Besides the above, the coupling interconnection 52 electrically couples the negative electrode 46 located in the sixth photoelectric conversion area 34 and the positive electrode 45 located in the seventh photoelectric conversion area 35 to each other. Besides the above, the coupling interconnection 52 electrically couples the negative electrode 46 located in the seventh photoelectric conversion area 35 and the positive electrode 45 located in the eighth photoelectric conversion area 36 to each other. Besides the above, the coupling interconnection 52 electrically couples the negative electrode 46 located in the eighth photoelectric conversion area 36 and the positive electrode 45 located in the first photoelectric conversion area 29 to each other.

As described above, the n+ impurity area 48 disposed in the first photoelectric conversion area 29 and the p+ impurity area 47 disposed in the second photoelectric conversion area 30 are electrically coupled to each other by the positive electrode 45, the negative electrode 46, and the coupling interconnection 52. Further, the coupling interconnection 52 is disposed so as to pass above the first insulating area 37.

On the lower side in the drawing of the positive electrode 45 and the negative electrode 46, there is disposed a third insulating film 53 so as to cover the positive electrode 45 and the negative electrode 46. As the material of the third insulating film 53, there can be used a silicon dioxide film or a silicon nitride film. In the present embodiment, for example, a silicon nitride film is used as the material of the third insulating film 53. As the material of the positive electrode 45 and the negative electrode 46, it is possible to use metal such as aluminum, titanium, or copper, or an alloy. In the present embodiment, for example, an aluminum alloy is used as the material of the positive electrode 45 and the negative electrode 46.

When the semiconductor substrate 38 is irradiated with the light 41, the electrons absorb the light to be excited, and thus, free holes 54 and free electrons 55 are generated inside the semiconductor substrate 38. The free holes are holes which are separated from atoms and become movable, and the free electrons are electrons which are separated from atoms and become movable. Then, the free holes and the free electrons disperse inside the semiconductor substrate. A depletion layer is formed between the p+ impurity area 47 and the n-type semiconductor substrate 38.

In the depletion layer, there is formed a built-in electric field. When the hole or the electron reaches the depletion layer, the hole or the electron migrates along the electric field. The holes approaching the positive electrode 45 flow toward the positive electrode 45, and the positive electrode 45 becomes an electrode on the positive side. The electrons approaching the negative electrode 46 flow toward the negative electrode 46, and the negative electrode 46 becomes an electrode on the negative side.

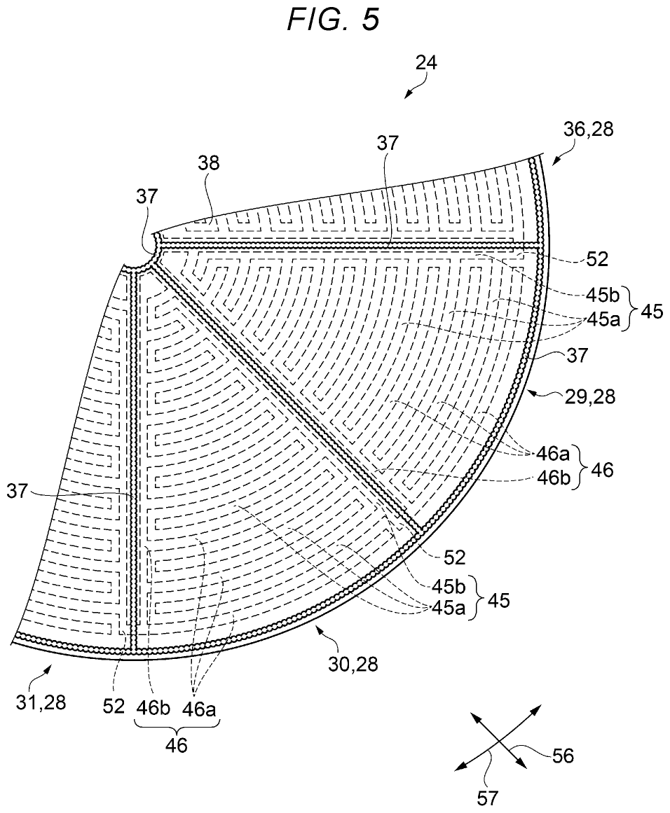

FIG. 5 is a schematic plan view of a principal part showing a structure of the positive electrode and the negative electrode, and is a diagram of the first photoelectric conversion area 29 and the second photoelectric conversion area 30 viewed from the first surface 38b side. As shown in FIG. 5, the photoelectric conversion device 24 has a shape approximate to a shape obtained by dividing a circle into eight equal parts with lines passing through the center of the circle.

The photoelectric conversion device 24 and the semiconductor substrate 38 each have a circular shape. A direction in which a line passing through the center of the circular shape extends on the surface of the first surface 38b of the semiconductor substrate 38 is defined as a radial direction 56. A direction perpendicular to the radial direction 56 is defined as a circumferential direction 57.

In the first photoelectric conversion area 29 surrounded by the first insulating area 37, there are disposed the positive electrode 45 and the negative electrode 46. The positive electrode 45 is provided with positive finger electrodes 45a and a positive bus electrode 45b. The positive finger electrodes 45a are each an electrode having an arc-like shape elongated in the circumferential direction 57, and the plurality of positive finger electrodes 45a is arranged in the radial direction 56. The positive bus electrode 45b is electrically coupled to the plurality of positive finger electrodes 45a. The positive bus electrode 45b is a single electrode extending in the radial direction 56.

Similarly, the negative electrode 46 is provided with negative finger electrodes 46a and a negative bus electrode 46b. The negative finger electrodes 46a are each an electrode having an arc-like shape elongated in the circumferential direction 57, and the plurality of negative finger electrodes 46a is arranged in the radial direction 56. The negative bus electrode 46b is electrically coupled to the plurality of negative finger electrodes 46a. The negative bus electrode 46b is a single electrode extending in the radial direction 56.

The positive finger electrodes 45a and the negative finger electrodes 46a are alternately arranged in the radial direction 56. Further, the semiconductor substrate 38 in the areas opposed to the positive finger electrodes 45a is provided with the p+ impurity areas 47 formed at predetermined intervals. The semiconductor substrate 38 in the areas opposed to the negative finger electrodes 46a is provided with the n+ impurity areas 48 formed at predetermined intervals. The number of the positive finger electrodes 45a and the negative finger electrodes 46a is not particularly limited. In order to make the drawing eye-friendly, in the drawing, the number of the positive finger electrodes 45a is set to eight, and the number of the negative finger electrodes 46a is set to nine.

Further, the negative electrode 46 of the first photoelectric conversion area 29 and the positive electrode 45 of the second photoelectric conversion area 30 are electrically coupled to each other by the coupling interconnection 52. The coupling interconnection 52 is disposed so as to pass above the first insulating area 37. The first photoelectric conversion area 29 through the eighth photoelectric conversion area 36 of the semiconductor substrate 38 are insulated from each other by the first insulating area 37. Therefore, each of the first photoelectric conversion area 29 through the eighth photoelectric conversion area 36 individually generates power.

Further, since the coupling interconnection 52 electrically couple the negative electrode 46 of the first photoelectric conversion area 29 and the positive electrode 45 of the second photoelectric conversion area 30 to each other, the first photoelectric conversion area 29 and the second photoelectric conversion area 30 are coupled in series to each other. Similarly, the fifth photoelectric conversion area 33, the sixth photoelectric conversion area 34, the seventh photoelectric conversion area 35, the eighth photoelectric conversion area 36, the first photoelectric conversion area 29, the second photoelectric conversion area 30, the third photoelectric conversion area 31, and the fourth photoelectric conversion area 32 are electrically coupled in series in this order.

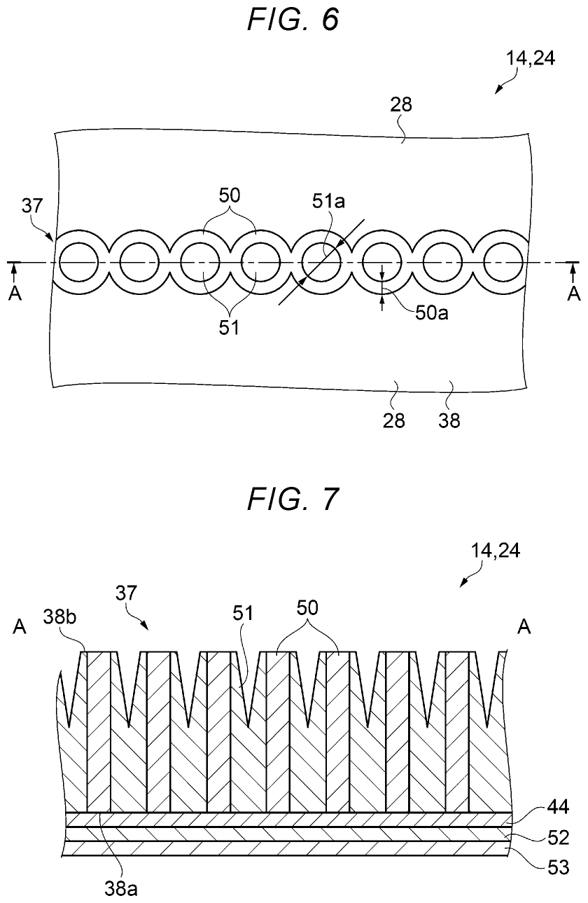

FIG. 6 is a schematic plan view for explaining the insulating area, and is a diagram of the photoelectric conversion device 24 viewed from the first surface 38b side. FIG. 7 is a schematic side cross-sectional view for explaining the insulating area, and is a diagram of the photoelectric conversion device 24 viewed from a plane along the line AA in FIG. 6. As shown in FIG. 6 and FIG. 7, when viewed from the thickness direction of the semiconductor substrate 38, the shape of the second insulating film 50 is a shape obtained by connecting circular rings in a row. A part shaped like the circular ring is elongated in the thickness direction of the semiconductor substrate 38, and has, therefore, a cylindrical shape. The second insulating film 50 is disposed between the second surface 38a and the first surface 38b. Therefore, when the second insulating film 50 is made continuous, it is possible to electrically isolate the photoelectric conversion areas 28 adjacent to each other from each other.

Inside each of the parts shaped like the circular ring of the second insulating film 50, there is disposed the first reinforcing part 51. The first reinforcing part 51 has a columnar shape, and on the first surface 38b side, the center of the first reinforcing part 51 is recessed. The diameter of the first reinforcing part 51 when viewed from the thickness direction of the semiconductor substrate 38 is defined as a reinforcing part diameter 51a. It is preferable for the reinforcing part diameter 51a to be no smaller than 6 μm and no larger than 16 μm. When the diameter is smaller than 6 μm, it becomes difficult to dispose the material of the first reinforcing part 51 inside the second insulating film 50. Further, when the diameter is larger than 16 μm, the width of the first insulating area 37 becomes large, and therefore, the proportion of the area occupied by the photoelectric conversion areas 28 in the photoelectric conversion device 24 becomes small, and thus, the power generation efficiency becomes low.

The width of the Si oxide shaped like the circular ring in the second insulating film 50 is defined as a second insulating film width 50a. It is preferable for the second insulating film width 50a to be no smaller than 1 μm and no larger than 5 μm. The width of the circular ring represents an average value of a number of the circular rings formed. The part shaped like the circular ring is formed by thermally oxidizing a hole provided to the semiconductor substrate 38 including silicon. The distance between the first reinforcing parts 51 adjacent to each other when the circular rings are connected to each other in a row is no smaller than 2 μm which is twice as large as the second insulating film width 50a. Since the width of the circular ring is made substantially twice due to the thermal oxidation, the holes are formed in the process prior to the thermal oxidation so that the distance between the side surfaces of the holes is no smaller than 1 μm. When the distance between the side surfaces of the holes becomes smaller than 1 μm, there arises a possibility that the holes adjacent to each other merge with each other to fail to form the circular rings due to a variation when processing the holes. By making the distance between the side surfaces of the holes no smaller than 1 μm, it is possible to form the circular rings connected to each other in a row with high quality. Therefore, it is preferable for the second insulating film width 50a to be no smaller than 1 μm. Further, when the second insulating film width 50a exceeds 5 μm, the time for which the silicon is oxidized is elongated. By making the second insulating film width 50a no larger than 5 μm, it is possible to form the second insulating film 50 with high productivity.

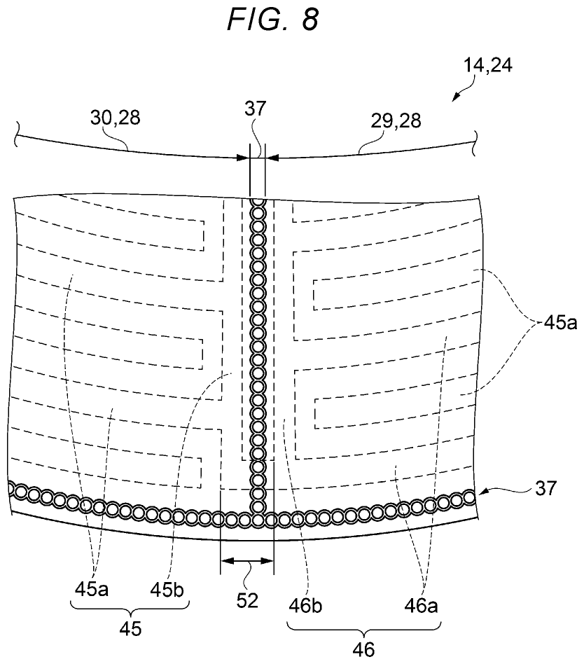

FIG. 8 is a schematic plan view of a principal part for explaining the coupling interconnection. In FIG. 8, the first photoelectric conversion area 29 is disposed on the right side in the drawing, and the second photoelectric conversion area 30 is disposed on the left side in the drawing. Further, the first insulating area 37 is disposed between the first photoelectric conversion area 29 and the second photoelectric conversion area 30.

The coupling interconnection 52 electrically couples the negative electrode 46 of the first photoelectric conversion area 29 and the positive electrode 45 of the second photoelectric conversion area 30 to each other. The negative electrode 46, the positive electrode 45, and the coupling interconnection 52 are the same in material, and are formed integrally. Further, the coupling interconnection 52 is disposed so as to pass above the first insulating area 37. Therefore, the first photoelectric conversion area 29 and the second photoelectric conversion area 30 are electrically coupled to each other only by the coupling interconnection 52.

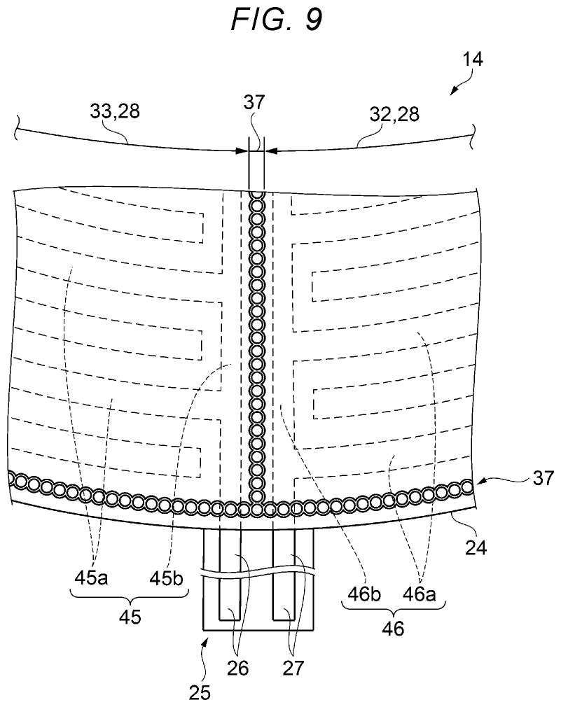

FIG. 9 is a schematic plan view of a principal part for explaining the wiring board. In FIG. 9, the fourth photoelectric conversion area 32 is disposed on the right side in the drawing, and the fifth photoelectric conversion area 33 is disposed on the left side in the drawing. Further, the first insulating area 37 is disposed between the fourth photoelectric conversion area 32 and the fifth photoelectric conversion area 33.

On the outer circumferential side of the photoelectric conversion device 14, the wiring board 25 is disposed between the fourth photoelectric conversion area 32 and the fifth photoelectric conversion area 33. On the wiring board 25, there are disposed the first board interconnection 26 and the second board interconnection 27. Further, the first board interconnection 26 is electrically coupled to the positive electrode 45 of the fifth photoelectric conversion area 33. The second board interconnection 27 is electrically coupled to the negative electrode 46 of the fourth photoelectric conversion area 32.

The fifth photoelectric conversion area 33, the sixth photoelectric conversion area 34, the seventh photoelectric conversion area 35, the eighth photoelectric conversion area 36, the first photoelectric conversion area 29, the second photoelectric conversion area 30, the third photoelectric conversion area 31, and the fourth photoelectric conversion area 32 are electrically coupled in series in this order. Therefore, the first board interconnection 26 and the second board interconnection 27 are electrically coupled to electrodes at the both ends of the photoelectric conversion areas 28 thus coupled in series.

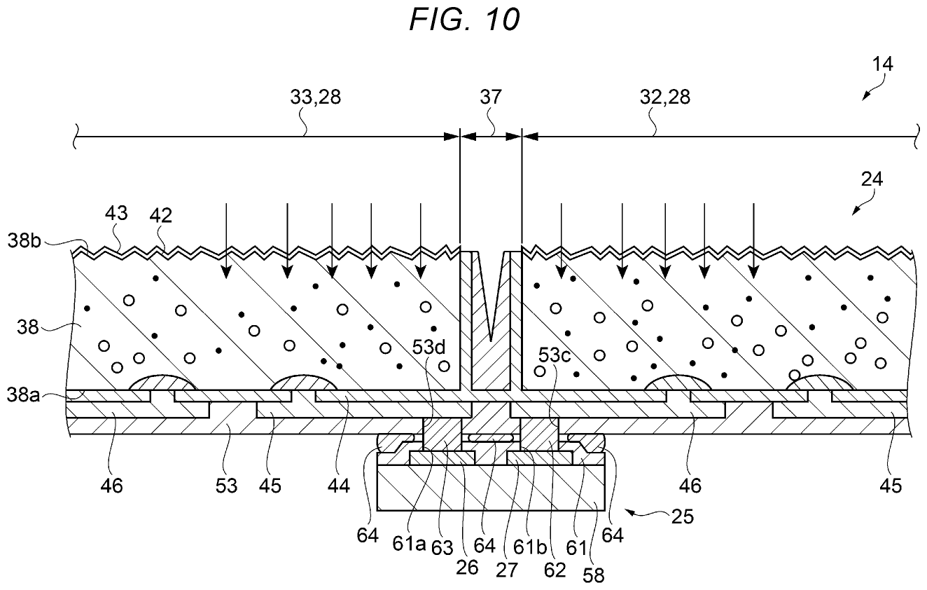

FIG. 10 is a schematic side cross-sectional view of a principal part of the wiring board for explaining the wiring board. As shown in FIG. 10, the photoelectric conversion module 14 is provided with the photoelectric conversion device 24 and the wiring board 25. The wiring board 25 is provided with an insulating substrate 58. On the insulating substrate 58, there are disposed the first board interconnection 26 and the second board interconnection 27.

A fifth insulating film 61 is disposed so as to be stacked on the first board interconnection 26, the second board interconnection 27, and the insulating substrate 58. The fifth insulating film 61 is provided with a ninth hole 61a formed in a part of an area opposed to the first board interconnection 26. In the ninth hole 61a, there is exposed the first board interconnection 26. The fifth insulating film 61 is provided with a tenth hole 61b formed in a part of an area opposed to the second board interconnection 27. In the tenth hole 61b, there is exposed the second board interconnection 27.

The third insulating film 53 of the photoelectric conversion device 24 is provided with an eleventh hole 53c formed in a part of an area opposed to the negative electrode 46 of the fourth photoelectric conversion area 32. In the eleventh hole 53c, there is exposed the negative electrode 46. The third insulating film 53 of the photoelectric conversion device 24 is provided with a twelfth hole 53d formed in a part of an area opposed to the positive electrode 45 of the fifth photoelectric conversion area 33. In the twelfth hole 53d, there is exposed the positive electrode 45.

When viewed from the thickness direction of the semiconductor substrate 38, the eleventh hole 53c and the tenth hole 61b are disposed so as to be opposed to each other. Further, in an area where the eleventh hole 53c and the tenth hole 61b are disposed, a negative electrode conductive coupling part 62 is disposed between the second board interconnection 27 and the negative electrode 46. The negative electrode conductive coupling part 62 electrically couples the second board interconnection 27 and the negative electrode 46 to each other. In an area where the twelfth hole 53d and the ninth hole 61a are disposed, a positive electrode conductive coupling part 63 is disposed between the first board interconnection 26 and the positive electrode 45. The positive electrode conductive coupling part 63 electrically couples the first board interconnection 26 and the positive electrode 45 to each other. The wiring board 25 and the photoelectric conversion device 24 are bonded to be fixed to each other with an adhesive 64. It should be noted that when the wiring board 25 and the photoelectric conversion device 24 can be bonded to each other without using the adhesive 64, it is not required to use the adhesive 64.

As the insulating substrate 58, there is used a variety of types of resin substrate such as a polyimide substrate or a polyethylene terephthalate substrate. In the present embodiment, for example, a polyimide substrate is used as the insulating substrate 58. As the first board interconnection 26 and the second board interconnection 27, there is used copper or a copper alloy, aluminum or an aluminum alloy, silver or a silver alloy, or the like. In the present embodiment, for example, as the first board interconnection 26 and the second board interconnection 27, there is used copper.

As the negative electrode conductive coupling part 62 and the positive electrode conductive coupling part 63, there is used a conductive paste, a conductive sheet, an electrically conductive adhesive, a metal material, solder, a brazing material, or the like. In the present embodiment, for example, a conductive paste is used as the negative electrode conductive coupling part 62 and the positive electrode conductive coupling part 63.

As the material of the fifth insulating film 61, there is used a variety of types of resin material such as polyimide resin or polyethylene terephthalate resin. In the present embodiment, for example, polyimide resin is used as the material of the fifth insulating film 61.

As the material of the adhesive 64, there is used an epoxy adhesive, a silicone adhesive, an olefinic adhesive, an acrylic adhesive, or the like. In the present embodiment, for example, an epoxy adhesive is used as the material of the adhesive 64.

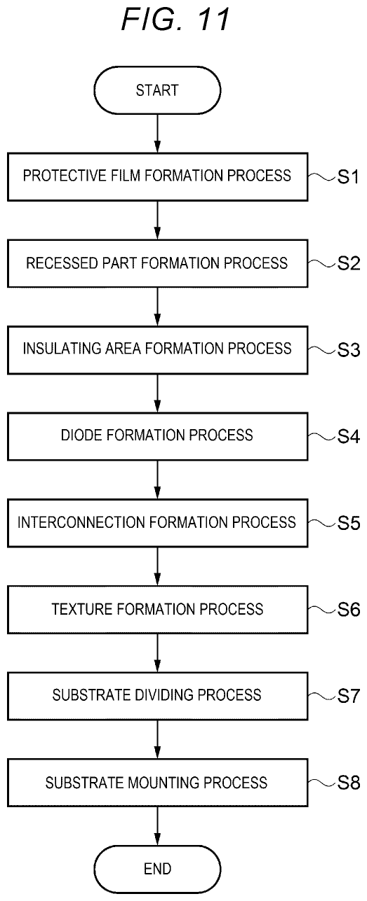

Then, a method of manufacturing the photoelectric conversion module 14 described above will be described with reference to FIG. 11 through FIG. 26. FIG. 11 is a flowchart of the method of manufacturing the photoelectric conversion module, and FIG. 12 through FIG. 26 are schematic diagrams for explaining the method of manufacturing the photoelectric conversion module. In the flowchart shown in FIG. 11, the step S1 corresponds to a protective film formation process, and is a process of forming a protective film on a silicon wafer. Then, the transition to the step S2 is made. The step S2 corresponds to a recessed part formation process. This process is a process of forming recessed parts to be the bases of the third holes 49. Then, the transition to the step S3 is made. The step S3 corresponds to an insulating area formation process. This process is a process of providing the second insulating film 50 and the first reinforcing part 51 to each of the recessed parts.

Then, the transition to step S4 is made. The step S4 corresponds to a diode formation process. This process is a process of forming the diodes in the semiconductor substrate 38. Then, the transition to the step S5 is made. The step S5 corresponds to an interconnection formation process. This process is a process of forming the positive electrodes 45 and the negative electrodes 46 on the semiconductor substrate 38. Then, the transition to the step S6 is made. The step S6 corresponds to a texture formation process. This process is a process of providing the texture 42 to the first surface 38b of the semiconductor substrate 38. Then, the transition to the step S7 is made. The step S7 corresponds to a substrate dividing process. This process is a process of dividing the silicon wafer to form the shape of the photoelectric conversion device 24. Then, the transition to the step S8 is made. The step S8 corresponds to a substrate mounting process. This process is a process of mounting the photoelectric conversion device 24 on the wiring board 25. Due to the processes described hereinabove, the photoelectric conversion module 14 is completed.

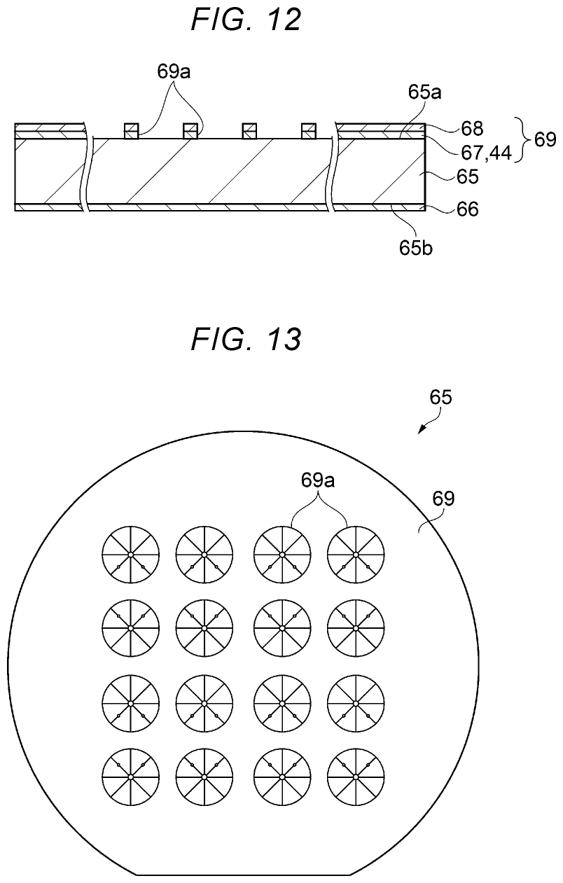

Then, the manufacturing method will be described in detail in association with the steps shown in FIG. 11 using FIG. 12 through FIG. 26. FIG. 12 through FIG. 13 are diagrams corresponding to the protective film formation process in the step S1. As shown in FIG. 12, a silicon wafer 65 as the semiconductor substrate is prepared. The silicon wafer 65 is ground to have a predetermined thickness, and the surface thereof is polished. Further, the surface is etched to decrease the lattice defects. The silicon wafer 65 is a mother substrate in which a plurality of the photoelectric conversion devices 24 is formed.

The silicon wafer 65 has a disk-like shape, and has two planes opposed to each other. One of the two planes is defined as a second surface 65a, and the other of the planes is defined as a first surface 65b. A first protective film 66 is deposited on the first surface 65b. The first protective film 66 is a silicon nitride film. The first protective film 66 is deposited using a PECVD (plasma enhanced chemical vapor deposition) method.

A silicon oxide film 67 and a silicon nitride film 68 are deposited on the second surface 65a side of the silicon wafer 65 in a stacked manner. The silicon oxide film 67 and the silicon nitride film 68 constitute a second protective film 69. The second protective film 69 is a film functioning as a mask when forming the recessed parts to be the bases of the third holes 49. The silicon oxide film 67 and the silicon nitride film 68 are deposited using a vapor deposition method, a sputtering method, or a CVD (chemical vapor deposition) method. The thickness of each of the silicon oxide film 67 and the silicon nitride film 68 is not particularly limited. In the present embodiment, for example, the film thickness of the silicon oxide film 67 is in a range of 100 nm through 200 nm. The film thickness of the silicon nitride film 68 is in a range of 100 nm through 200 nm.

A resist film not shown is deposited so as to be stacked on the silicon oxide film 67 and the silicon nitride film 68. A resin solution having photosensitive resin dissolved is applied using a spin coat method, a spray coat method, or the like. Then, the solvent is removed by drying the resin solution to form the resin film. As the photosensitive resin, it is possible to adopt a material of either of the negative type and the positive type. Then, the resist film is exposed using a photolithography technology. Then, the resist film is developed. The resist film thus developed is provided with opening parts, and thus, the resist film functions as an etching mask. The opening part is a part where the silicon oxide film 67 and the silicon nitride film 68 are removed from the second protective film 69. Then, the second protective film 69 is etched using the resist film as a mask. The second protective film 69 is provided with the second opening parts 69a in the pattern of the first insulating area 37. The silicon oxide film 67 is formed in a predetermined pattern to form the first insulating film 44. Therefore, the first insulating film 44 and the silicon nitride film 68 constitute the second protective film 69.

Subsequently, the resist film disposed on the silicon wafer 65 is removed. The removal of the resist film can be performed by a wet etching method with fuming nitric acid, sulfuric acid, an organic solvent, or the like capable of dissolving/separating the resist film, oxygen plasma ashing, or the like. In the present embodiment, for example, ashing is performed using the oxygen plasma ashing, and then the residues of the resist film is further removed using an organic removing liquid or sulfuric acid.

FIG. 13 shows the planar shape of the second protective film 69 provided with the second opening parts 69a. As shown in FIG. 13, the pattern of the second opening parts 69a is formed on the silicon wafer 65 so that the 4×4 photoelectric conversion devices 24 are formed. It should be noted that the number of the photoelectric conversion devices 24 to be formed in one silicon wafer 65 is not particularly limited. In the present embodiment, in order to make the drawings eye-friendly, it is assumed that the 16 photoelectric conversion devices 24 are formed in one silicon wafer 65.

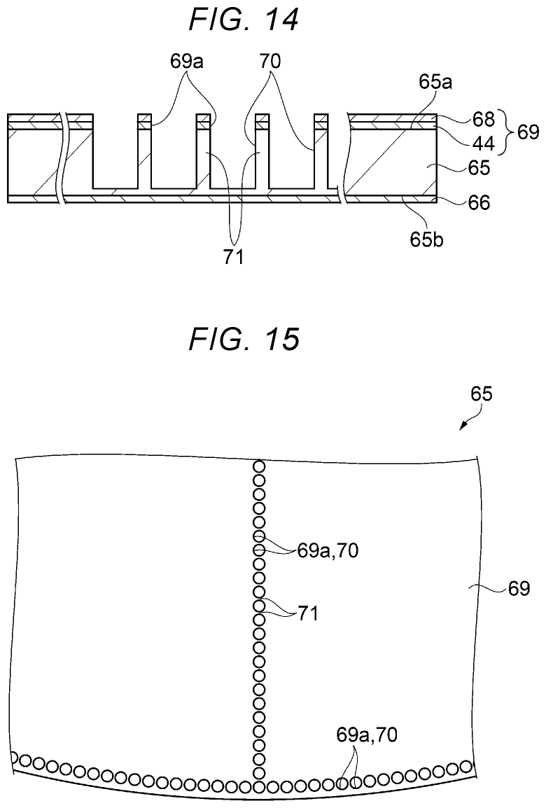

FIG. 14 and FIG. 15 are diagrams corresponding to the recessed part formation process in the step S2. FIG. 14 is a side cross-sectional view of a principal part of recessed parts 70, and FIG. 15 is a plan view viewed from the thickness direction of the silicon wafer 65. As shown in FIG. 14 and FIG. 15, anisotropic etching is subsequently performed on the silicon wafer 65 using the second protective film 69 as a mask. As the anisotropic etching, it is possible to use, for example, deep reactive ion etching (DRIE) with inductive coupled plasma (ICP).

The deep reactive ion etching with the inductive coupled plasma is performed using an anisotropic etching device. The anisotropic etching device is provided with a stage and a coil in a chamber. The silicon wafer 65 is mounted on the stage so that the second surface 65a on which the second protective film 69 is formed faces to the coil.

By making a high current with a high frequency flow through the coil while supplying an SF₆ gas inside the chamber, the plasma is generated. Then, by applying a bias voltage to the stage, the particles of the plasma are attracted toward the second surface 65a of the silicon wafer 65 from the second opening parts 69a of the second protective film 69. Thus, the silicon wafer 65 is etched substantially vertically in the thickness direction from the second surface 65a side with the shape of the second opening parts 69a. The silicon thus etched is removed as SiF₄. In order to prevent excessive rise in temperature of the silicon wafer 65, the anisotropic etching device cools the silicon wafer 65 from the first surface 65b side using, for example, helium gas.

The silicon wafer 65 is etched to predetermined depth using the anisotropic etching device. Then, the anisotropic etching device supplies C₄F₈ gas to the surface of the silicon wafer 65. Due to the C₄F₈ gas, a third protective film not shown is formed. The formation of the third protective film is referred to as coating.

The silicon wafer 65 is etched once again in the thickness direction. Due to the etching, silicon is exposed. Then, coating with the third protective film is performed. Then, etching of the silicon wafer 65 and coating with the third protective film are repeated. This method is called a Bosch process. As a result, the second surface 65a of the silicon wafer 65 is provided with the recessed parts 70 arranged at predetermined intervals. The depth of the recessed part 70 is not particularly limited, but is set to, for example, 250 μm in the present embodiment. Silicon remains between the recessed parts 70. This part is called a bridge 71. When the recessed parts 70 adjacent to each other are connected to each other make the bridge 71 disappear, the possibility that the silicon wafer 65 is broken when grinding the silicon wafer 65 in a posterior process becomes high. Therefore, the recessed parts 70 are arranged so that the bridges 71 do not disappear.

The recessed part 70 is a blind hole having a cylindrical shape. The diameter of the recessed part 70 is not particularly limited, but is set to, for example, no smaller than 5 μm and no larger than 10 μm in the present embodiment. When the diameter of the recessed part 70 is smaller than 5 μm, since the particles of the plasma become difficult to enter the recessed part 70, the time for forming the recessed part 70 is elongated, and therefore, the productivity is lowered. When the diameter of the recessed part 70 exceeds 10 μm, the photoelectric conversion area 28 becomes narrow. Further, since the width of the first insulating area 37 becomes wide, the first insulating area 37 becomes easy to visually recognize. Therefore, it is not preferable from the viewpoint of the appearance of the photoelectric conversion device 24.

The width of the bridge 71 is not particularly limited, but is set to, for example, no smaller than 1 μm and no larger than 5 μm in the present embodiment. When the width of the bridge 71 becomes smaller than 1 μm, there is a possibility that the recessed parts 70 adjacent to each other are connected to each other due to the variation when processing the recessed parts 70. When the recessed parts 70 adjacent to each other are connected to each other, the bridge 71 disappears. By making the width of the bridge 71 no smaller than 1 μm, it is possible to form the first insulating area 37 with high quality. When the width of the bridge 71 exceeds 5 μm, the time for oxidizing silicon in the bridge 71 in a posterior process becomes long. By making the width of the bridge 71 no larger than 5 μm, it is possible to form the first insulating area 37 shaped like a circular ring with high productivity.

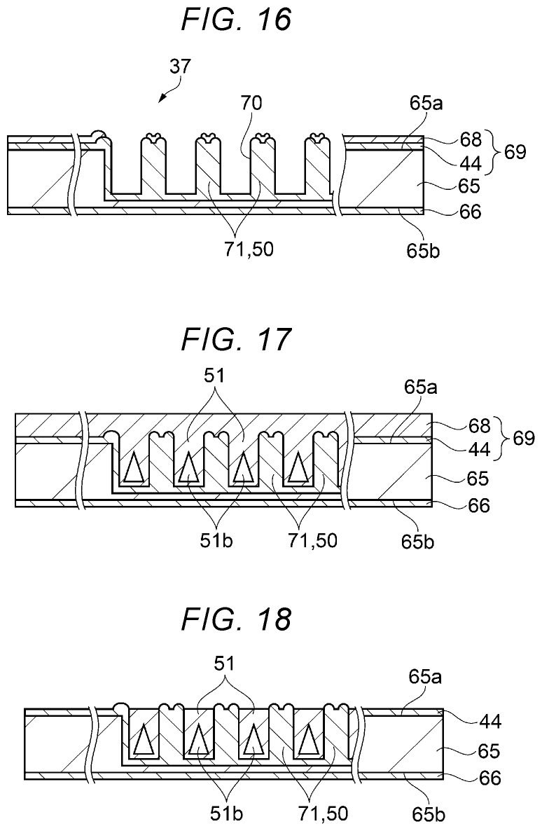

FIG. 16 through FIG. 18 are diagrams corresponding to the insulating area formation process in the step S3. As shown in FIG. 16, in the step S3, the second insulating film 50 is deposited on the recessed parts 70. The second insulating film 50 is a film of an Si oxide made of silicon dioxide or the like. As a method of forming the second insulating film 50, it is possible to use a method using an oxidation furnace. The second insulating film 50 is deposited using the oxidation furnace. The silicon wafer 65 is put in the oxidation furnace formed of a quartz tube heated to a range of 900 through 1100 degrees, and then a gas such an oxygen or hydrogen is introduced. Then, the silicon wafer 65 is heated for about 120 hours. By this operation, silicon is oxidized to form the second insulating film 50. The second insulating film 50 is formed on the sidewall of the recessed part 70 so as to have the circular ring shape. Silicon of the recessed parts 70 is thermally oxidized in such a manner, and thus, the second insulating film 50 including the Si oxide having a shape obtained by connecting the circular rings in a row is formed in the first insulating area 37. Since an electrical current flows through the first insulating area 37 when silicon remains in the bridge 71, it is necessary to surely change silicon in the bridge 71 to the Si oxide to form the second insulating film 50.

When silicon turns to the Si oxide in the bridge 71, the width of the bridge 71 doubles. Therefore, the width of the bridge 71 after oxidizing silicon becomes no smaller than 2 μm and no larger than 10 μm. The second insulating film width 50a is made half as large as the width of the bridge 71. Therefore, the second insulating film width 50a becomes no smaller than 1 μm and no larger than 5 μm.

Subsequently, as shown in FIG. 17, the first reinforcing part 51 is formed inside each of the recessed parts 70. In the present embodiment, for example, the first reinforcing part 51 is made of an Si nitride, and is the same in material as the silicon nitride film 68. The first reinforcing parts 51 are disposed using a CVD method. In the CVD method, the silicon nitride is turned into a spray, and is then deposited on the silicon wafer 65.

On this occasion, in the recessed part 70, the silicon nitride is easy to adhere to the side surface of an entrance part, and is difficult to adhere to a bottom part of the recessed part 70. Therefore, in the recessed part 70, a lid made of the silicon nitride is formed in the entrance part. Then, a hollow 51b is formed in the back part of the recessed part 70. Since the recessed part 70 has the cylindrical shape, the hollow 51b is provided with a conical shape. Since it is sufficient for the first reinforcing part 51 to reinforce the strength of the bridge 71, existence of the hollow 51b is allowed. Since the silicon nitride is also deposited on the silicon nitride film 68, the silicon nitride film 68 thickens.

Then, as shown in FIG. 18, the silicon nitride film 68 is removed. The method of removing the silicon nitride film 68 is not particularly limited, but in the present embodiment, for example, an anisotropic dry etching method is used. The silicon nitride film 68 is removed to expose the first insulating film 44. The first insulating film 44 is a film of a silicon oxide, and functions as an insulating film.

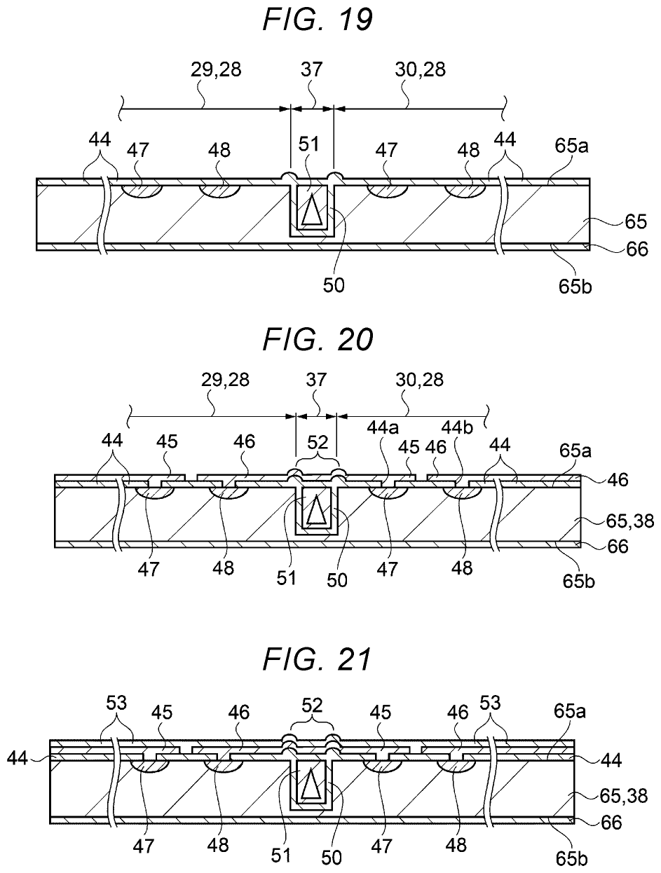

FIG. 19 is a diagram corresponding to the diode formation process in the step S4. As shown in FIG. 19, in the step S4, the diodes are formed. Firstly, silicon oxide is deposited so as to be stacked on the first insulating film 44 to adjust the thickness of the first insulating film 44. The film of silicon oxide is deposited and then formed to have a predetermined pattern by substantially the same method as the method used in the step S1. Then, the p+ impurity areas 47 are formed. Similarly to the case of the step S1, a resist film is deposited on the second surface 65a side of the silicon wafer 65. Then, the resist film is exposed and then developed using a photolithography technology. The resist film thus developed is provided with openings having the shapes of the p+ impurity areas 47. The resist film is used as an ion injection mask.

Subsequently, ion injection with boron is performed on the silicon wafer 65. The injection depth of boron is controlled by controlling the injection angle with respect to the thickness direction of the silicon wafer 65. Further, by performing the ion injection through the first insulating film 44, it is possible to shallowly inject boron. Subsequently, the resist film is removed. As the method of removing the resist film, the same method as in the step S1 is used.

Then, the n+ impurity areas 48 are formed. Similarly to the case of the step S1, a resist film is deposited on the second surface 65a side of the silicon wafer 65. Then, the resist film is exposed and then developed using a photolithography technology. The resist film thus developed is provided with openings having the shapes of the n+ impurity areas 48. The resist film is used as an ion injection mask.

Subsequently, ion injection with phosphorus is performed on the silicon wafer 65. The injection depth of phosphorus is controlled by controlling the injection angle with respect to the thickness direction of the silicon wafer 65. Further, by performing the ion injection through the first insulating film 44, it is possible to shallowly inject phosphorus. Subsequently, the resist film is removed. As the method of removing the resist film, the same method as in the step S1 is used.

Then, the silicon wafer 65 is heated to thereby replace silicon with boron or phosphorus thus injected. Since silicon and phosphorus or boron are different in valence from each other, the number of superfluous electrons or the hole concentration increases. Further, in the silicon crystal having boron or phosphorus disposed, the electrical nature changes from the semiconductor and approaches the metal. In such a manner, the n+ impurity areas 48 and the p+ impurity areas 47 different from the n+ impurity areas 48 are formed in each of the first photoelectric conversion area 29 and the second photoelectric conversion area 30 located across the first insulating area 37.

FIG. 20 and FIG. 21 are diagrams corresponding to the interconnection formation process in the step S5. As shown in FIG. 20, in the step S5, first holes 44a and second holes 44b are formed in the first insulating film 44.

When forming the first holes 44a and the second holes 44b, a resist film is deposited on the second surface 65a side of the silicon wafer 65 similarly to the case of the step S1. Then, the resist film is exposed and then developed using a photolithography technology. The resist film thus developed is provided with openings having the shapes of the first holes 44a and the second holes 44b. The resist film is used as an etching mask. Then, the silicon wafer 65 is irradiated with oxygen plasma, and further, the silicon wafer 65 is dipped in a buffered hydrofluoric acid to form the first holes 44a and the second holes 44b. Subsequently, the resist film is removed.

Then, the positive electrodes 45, the negative electrodes 46, and the coupling interconnections 52 are formed on the first insulating film 44. The positive electrodes 45, the negative electrodes 46, and the coupling interconnections 52 each have a double-layered structure with a first layer and a second layer. The material of the first layer is an aluminum-silicon alloy. The material of the second layer is titanium nitride. The first layer is deposited on the first insulating film 44 by a sputtering method. Then, the second layer is deposited on the first layer by a sputtering method.

The first layer is made higher in reflectance than the second layer. Therefore, apart of the light 41 transmitted through the semiconductor substrate 38 is reflected by the positive electrode 45, the negative electrode 46, and the coupling interconnection 52 at a high rate, and then proceeds toward the semiconductor substrate 38. Therefore, it is possible for the semiconductor substrate 38 to efficiently absorb the light 41.

Then, a resist film is deposited to the second surface 65a side of the silicon wafer 65. Then, the resist film is exposed and then developed using a photolithography technology. The resist film thus developed is provided with the shapes of the positive electrodes 45, the negative electrodes 46, and the coupling interconnections 52. The resist film is used as an etching mask. Then, the silicon wafer 65 is dipped in an etchant to provide the film for metal interconnections deposited as a double-layered film with the shapes of the positive electrodes 45, the negative electrodes 46, and the coupling interconnections 52. Subsequently, the resist film is removed. As a result, the positive electrodes 45, the negative electrodes 46, and the coupling interconnections 52 are formed on the first insulating film 44.

Then, as shown in FIG. 21, the third insulating film 53 is formed so as to be stacked on the first insulating film 44, the positive electrodes 45, the negative electrodes 46, and the coupling interconnections 52. The third insulating film 53 is a silicon nitride film. The third insulating film 53 is deposited using a CVD method. In such a manner, the positive electrode 45, the negative electrodes 46, and the coupling interconnections 52 are disposed. The positive electrode 45, the negative electrode 46, and the coupling interconnection 52 electrically couple the n+ impurity area 48 disposed in the first photoelectric conversion area 29 and the p+ impurity area 47 disposed in the second photoelectric conversion area 30 to each other. Further, the coupling interconnection 52 is disposed so as to pass above the first insulating area 37 disposed between the first photoelectric conversion area 29 and the second photoelectric conversion area 30.

Similarly, the positive electrode 45, the negative electrode 46, and the coupling interconnection 52 electrically couple the n+ impurity area 48 disposed in the second photoelectric conversion area 30 and the p+ impurity area 47 disposed in the third photoelectric conversion area 31 to each other. Further, the positive electrode 45, the negative electrode 46, and the coupling interconnection 52 electrically couple the n+ impurity area 48 disposed in the third photoelectric conversion area 31 and the p+ impurity area 47 disposed in the fourth photoelectric conversion area 32 to each other. Further, the positive electrode 45, the negative electrode 46, and the coupling interconnection 52 electrically couple the n+ impurity area 48 disposed in the fifth photoelectric conversion area 33 and the p+ impurity area 47 disposed in the sixth photoelectric conversion area 34 to each other.

Further, the positive electrode 45, the negative electrode 46, and the coupling interconnection 52 electrically couple the n+ impurity area 48 disposed in the sixth photoelectric conversion area 34 and the p+ impurity area 47 disposed in the seventh photoelectric conversion area 35 to each other. Further, the positive electrode 45, the negative electrode 46, and the coupling interconnection 52 electrically couple the n+ impurity area 48 disposed in the seventh photoelectric conversion area 35 and the p+ impurity area 47 disposed in the eighth photoelectric conversion area 36 to each other. Further, the positive electrode 45, the negative electrode 46, and the coupling interconnection 52 electrically couple the n+ impurity area 48 disposed in the eighth photoelectric conversion area 36 and the p+ impurity area 47 disposed in the first photoelectric conversion area 29 to each other.

Further, the coupling interconnection 52 is disposed so as to pass above the first insulating area 37 disposed between the second photoelectric conversion area 30 and the third photoelectric conversion area 31. Further, the coupling interconnection 52 is disposed so as to pass above the first insulating area 37 disposed between the third photoelectric conversion area 31 and the fourth photoelectric conversion area 32. Further, the coupling interconnection 52 is disposed so as to pass above the first insulating area 37 disposed between the fifth photoelectric conversion area 33 and the sixth photoelectric conversion area 34. Further, the coupling interconnection 52 is disposed so as to pass above the first insulating area 37 disposed between the sixth photoelectric conversion area 34 and the seventh photoelectric conversion area 35. Further, the coupling interconnection 52 is disposed so as to pass above the first insulating area 37 disposed between the seventh photoelectric conversion area 35 and the eighth photoelectric conversion area 36. Further, the coupling interconnection 52 is disposed so as to pass above the first insulating area 37 disposed between the eighth photoelectric conversion area 36 and the first photoelectric conversion area 29.

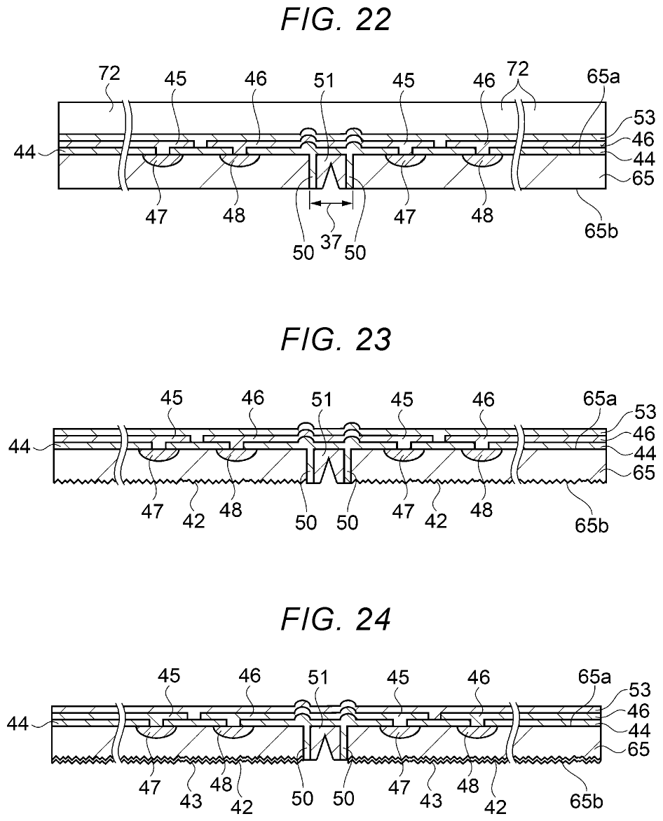

FIG. 22 through FIG. 24 are diagrams corresponding to the texture formation process in the step S6. As shown in FIG. 22, in the step S6, a second protective film 72 is deposited on the second surface 65a of the silicon wafer 65. The second protective film 72 is a film made of resin. As the deposition method of the second protective film 72, it is possible to use the same deposition method as the deposition method of the resist film in the step S1. Then, the first protective film 66 and the silicon wafer 65 are ground. In detail, the first surface 65b of the silicon wafer 65 is ground to expose the second insulating film 50 of the first insulating area 37 as the Si oxide on the first surface 65b. The silicon wafer 65 is ground by a grinder. By using a grinding stone having finer abrasive grains, it is possible to reduce a fractured layer. The thickness of the silicon wafer 65 after grinding is not particularly limited, but is set to, for example, about 170 μm in the present embodiment.

As shown in FIG. 23, the texture 42 is subsequently provided to the first surface 65b of the silicon wafer 65. The texture 42 is a surface having quadrangular pyramidal protrusions arranged tightly. For the formation of the texture 42, there is used, for example, a wet etching method. The wet etching method is performed using a solution which is obtained by adding isopropyl alcohol to an alkaline water solution of, for example, sodium hydroxide, potassium hydroxide, or tetramethylammonium hydroxide, and is heated to a temperature no lower than 70° C. and no higher than 80° C.

Then, the second protective film 72 is removed. As the removal method of the second protective film 72, it is possible to use the same removal method as the removal method of the resist film in the step S1.

As shown in FIG. 24, the antireflection film 43 is subsequently deposited on the first surface 65b. As the antireflection film 43, a silicon nitride film is deposited on the first surface 65b. Subsequently, silicon oxide films and silicon nitride films are alternately stacked to form a multilayer. Besides the above, it is also possible to alternately stack silicon oxide films and niobium oxide films to form a multilayer.

Subsequently, a heating treatment is performed as needed. This heating treatment is called a sintering process. Due to this heating treatment, it is possible to optimize the characteristic of the photoelectric conversion device 24.

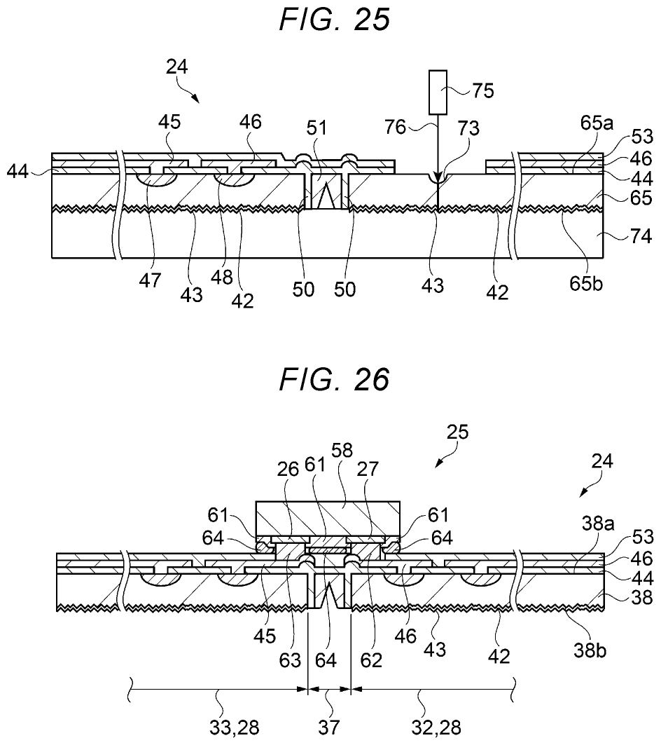

FIG. 25 is a diagram corresponding to the substrate dividing process in the step S7. As shown in FIG. 25, in the step S7, first grooves 73 are formed on the second surface 65a of the silicon wafer 65. The first grooves 73 are formed to have the outer shape of the photoelectric conversion device 24, the shapes of the hole 24a and the hole 24b, respectively. The first grooves 73 are formed using a photolithography method and an etching method known to the public, and therefore, the detailed description thereof will be omitted.

Then, dicing is performed along the outer periphery 24d of the photoelectric conversion device 24 to thereby divide the silicon wafer 65. Further, dicing is performed along the hole 24a and the hole 24b. Since the outer periphery 24d, the hole 24a, and the hole 24b are constituted by curved lines, a laser dicing method is used for dicing. Firstly, the first surface 65b of the silicon wafer 65 is stuck to an adhesive tape 74. A dicing ring not shown is stuck to the outer peripheral part of the adhesive tape 74. The dicing ring makes it easy to support the adhesive tape 74 and the silicon wafer 65 stuck to the adhesive tape 74.

Then, a laser dicing apparatus 75 is prepared. The laser dicing apparatus 75 is equipped with a laser source, an X-Y table, and a control device. The control device controls a displacement of the X-Y table, and emission of the laser source. The laser source is only required to be able to emit a laser beam 76 for cutting the silicon wafer 65, and is not particularly limited. In the present embodiment, for example, a YAG (yttrium aluminum garnet) laser is used as the laser source. The laser source emits the laser beam 76 with the wavelength of 355 nm to the silicon wafer 65. The laser source is provided with an optical system for converging the laser beam 76. Further, the control device controls the area on which the laser beam 76 is converged.

The silicon wafer 65 is set to the X-Y table not shown. Then, the control device controls the X-Y table so as to perform irradiation with the laser beam 76 along a path input in advance. The path irradiated with the laser beam 76 is set to a path for moving along the first grooves 73. Then, the laser dicing apparatus 75 performs the irradiation with the laser beam 76 along the first grooves 73 to divide the silicon wafer 65.

The laser source irradiates the first grooves 73 with the laser beam 76. The surfaces of the first grooves 73 are provided with irregularity, and thus, the first grooves 73 are made easy to absorb the laser beam 76. Therefore, since the silicon wafer 65 is efficiently heated by the laser beam 76, the silicon wafer 65 is cut with high productivity. Then, the photoelectric conversion devices 24 are taken out from the silicon wafer 65.

FIG. 26 is a diagram corresponding to the substrate mounting process in the step S8. As shown in FIG. 26, in the step S8, the photoelectric conversion device 24 is mounted on the wiring board 25. Firstly, the wiring board 25 is prepared. In the wiring board 25, the first board interconnection 26 and the second board interconnection 27 are formed on the insulating substrate 58 formed of polyimide. The first board interconnection 26 and the second board interconnection 27 are formed by printing a solution obtained by dispersing aluminum in a dispersion medium on the insulating substrate 58 using precision offset printing, and then drying the solution thus printed.

On the insulating substrate 58 on which the first board interconnection 26 and the second board interconnection 27 have been formed, a bonding layer and a fifth insulating film 61 are disposed. By laminating the insulating substrate 58 coated with the bonding layer made of an epoxy adhesive with the fifth insulating film 61 in a stacked manner, and then heating to solidify the bonding layer, the fifth insulating film 61 is bonded to be fixed to the insulating substrate 58.

Since the bonding layer and the fifth insulating film 61 are provided with holes at the positions opposed to the positive electrodes 45 or the negative electrodes 46, the first board interconnection 26 and the second board interconnection 27 are exposed. At the positions where the first board interconnection 26 or the second board interconnection 27 is exposed, there is disposed a conductive paste as the material of the negative electrode conductive coupling part 62 and the positive electrode conductive coupling part 63. Further, on the fifth insulating film 61, there is disposed the adhesive 64. The conductive paste and the adhesive 64 are disposed using a printing method such as a screen printing method.

Subsequently, the photoelectric conversion device and the wiring board 25 are stacked on each other. Subsequently, the photoelectric conversion device 24 and the wiring board 25 are pressed against each other to be made close to each other so as to have contact with each other. The conductive paste deforms under load to spread between the first board interconnection 26 and the positive electrode 45. Similarly, the conductive paste spreads between the second board interconnection 27 and the negative electrode 46. In this state, the conductive paste and the adhesive 64 are heated and then cure.

The conductive paste located between the first board interconnection 26 and the positive electrode 45 turns to the positive electrode conductive coupling part 63, and the conductive paste located between the second board interconnection 27 and the negative electrode 46 turns to the negative electrode conductive coupling part 62. As a result, the positive electrode conductive coupling part 63 has contact with both of the first board interconnection 26 and the positive electrode 45 to electrically and mechanically couple the first board interconnection 26 and the positive electrode 45 to each other. Similarly, the negative electrode conductive coupling part 62 has contact with both of the second board interconnection 27 and the negative electrode 46 to electrically and mechanically couple the second board interconnection 27 and the negative electrode 46 to each other. Due to the processes described hereinabove, the photoelectric conversion module 14 is completed.

As described above, according to the present embodiment, the following advantages are obtained.

(1) According to the present embodiment, the photoelectric conversion device 24 is provided with the semiconductor substrate 38. Further, in the semiconductor substrate 38, there are disposed the first photoelectric conversion area 29, the second photoelectric conversion area 30, and the first insulating area 37. The first photoelectric conversion area 29 and the second photoelectric conversion area 30 each receive light to convert the optical energy into the electrical energy. The first insulating area 37 is sandwiched between the first photoelectric conversion area 29 and the second photoelectric conversion area 30. Further, the first insulating area 37 electrically separates the first photoelectric conversion area 29 and the second photoelectric conversion area 30 from each other. Therefore, each of the first photoelectric conversion area 29 and the second photoelectric conversion area 30 individually generates power.

The semiconductor substrate 38 includes silicon, and the first insulating area 37 includes the Si oxide. Since the Si oxide is an insulator, it is possible for the first insulating area 37 to electrically separate the first photoelectric conversion area 29 and the second photoelectric conversion area 30 from each other. Further, the first insulating area 37 can be formed by providing the recessed parts 70 to the semiconductor substrate 38, and then thermally oxidizing the recessed parts 70.

By using the photolithography method, it is possible to finely form the recessed parts 70. Further, by thermally oxidizing the semiconductor substrate 38, it is possible to form the film of the Si oxide in each of the recessed parts 70. It is possible to set the film thickness of the Si oxide to several micrometers. The width of the first insulating area 37 when viewed from the thickness direction of the semiconductor substrate 38 becomes the length obtained by adding the width of the recessed part 70 and the film thickness of the Si oxide on the side surface of the recessed part 70 to each other. Therefore, the width of the insulating area becomes no larger than several tens of micrometers.

By cutting the semiconductor substrate 38 to separate the first photoelectric conversion area 29 and the second photoelectric conversion area 30 from each other, and then disposing the insulator between the first photoelectric conversion area 29 and the second photoelectric conversion area 30, it is possible to electrically separate the first photoelectric conversion area 29 and the second photoelectric conversion area 30 from each other. On this occasion, the distance between the first photoelectric conversion area 29 and the second photoelectric conversion area 30 becomes several millimeters. Compared to the photoelectric conversion device in which the first photoelectric conversion area 29 and the second photoelectric conversion area 30 are separated from each other, and the insulator is disposed therebetween, it is possible for the photoelectric conversion device 24 according to the present embodiment to shorten the width of the first insulating area 37. Therefore, it is possible for the photoelectric conversion device 24 to shorten the width of the insulating area between the first photoelectric conversion area 29 and the second photoelectric conversion area 30. Thus, it is possible to obtain the photoelectric conversion device 24 in which a certain distance is not provided between the first photoelectric conversion area 29 and the second photoelectric conversion area 30 in order to electrically separate the first photoelectric conversion area 29 and the second photoelectric conversion area 30 from each other, and thus the area of the photoelectric conversion area is not reduced.

(2) According to the present embodiment, when viewed from the thickness direction of the semiconductor substrate 38, the shape of the Si oxide in the first insulating area 37 is the shape having circular rings arranged in a row. By forming the recessed parts 70 each having a circular shape at regular intervals and then thermally oxidizing the semiconductor substrate 38, it is possible to easily form the first insulating area 37 to have the shape having the circular rings arranged in a row. Therefore, it is possible to form the first insulating area 37 using a simple method.

(3) According to the present embodiment, at the center of each of the circular rings of the first insulating area 37, there is disposed the first reinforcing part 51 formed of the Si compound. The circular rings of the first insulating area 37 are formed by thermally oxidizing the recessed parts 70. When arranging the recessed parts 70 at predetermined intervals, since the strength of the plane along the arrangement decreases, the semiconductor substrate 38 becomes easy to break. By disposing the first reinforcing parts 51 in the recessed parts 70, the strength of the plane along the arrangement increases, and therefore, it is possible to make the semiconductor substrate 38 difficult to break.

(4) According to the present embodiment, the second insulating film width 50a as the width of the circular ring is made no smaller than 1 μm and no larger than 5 μm. The second insulating film width 50a represents an average value of widths of a number of second insulating film 50 formed. The part shaped like the circular ring is formed by thermally oxidizing the recessed part 70 provided to the semiconductor substrate 38 including silicon. When the circular rings are connected to each other in a row, the distance between the circular rings adjacent to each other is no smaller than 2 μm. Since the width of the circular ring is made substantially twice due to the thermal oxidation, the recessed parts 70 are formed in the process prior to the thermal oxidation so that the distance between the side surfaces of the recessed parts is no smaller than 1 μm. When the distance between the side surfaces of the recessed parts 70 becomes smaller than 1 μm, there arises a possibility that the recessed parts 70 adjacent to each other merge with each other to fail to form the circular rings due to a variation when processing the recessed parts 70. By making the width of the circular ring no smaller than 1 μm, it is possible to form the circular rings connected to each other in a row with high quality. When the width of the circular ring exceeds 5 μm, the time for which the silicon is oxidized is elongated. By making the width of the circular ring no larger than 5 μm, it is possible to form the circular rings with high productivity.

(5) According to the present embodiment, the n+ impurity area 48 of the n+ type and the p+ impurity area 47 of the p+ type are disposed in the first photoelectric conversion area 29. The n+ impurity area 48 and the p+ impurity area 47 are also disposed in the second photoelectric conversion area 30. Further, the positive electrode 45, the negative electrode 46, and the coupling interconnection 52 electrically couple the n+ impurity area 48 disposed in the first photoelectric conversion area 29 and the p+ impurity area 47 disposed in the second photoelectric conversion area 30 to each other. The first photoelectric conversion area 29 and the second photoelectric conversion area 30 are coupled in series to each other by the coupling interconnection 52. Further, the coupling interconnection 52 is disposed on the semiconductor substrate 38. Therefore, it is possible for the photoelectric conversion device 24 to output a voltage obtained by adding a voltage output by the first photoelectric conversion area 29 and a voltage output by the second photoelectric conversion area 30 to each other.

(6) According to the present embodiment, the photoelectric conversion module 14 is provided with the photoelectric conversion device 24 and the wiring board 25. Further, the photoelectric conversion device 24 is capable of shortening the width of the first insulating area 37. Therefore, in the photoelectric conversion module 14, since the area of the first insulating area 37 is small, it is possible to increase the proportion of the area occupied by the first photoelectric conversion area 29 and the second photoelectric conversion area 30.

(7) According to the present embodiment, the wristwatch 1 is equipped with the photoelectric conversion module 14. Further, the photoelectric conversion module 14 is equipped with the photoelectric conversion device 24, and the photoelectric conversion device 24 is capable of shortening the width of the first insulating area 37. Therefore, it is possible for the wristwatch 1 to be formed as the equipment equipped with the photoelectric conversion module 14 capable of decreasing the area of the first insulating area 37 to increase the proportion of the area occupied by the first photoelectric conversion area 29 and the second photoelectric conversion area 30. Further, since the area of the first insulating area 37 is small, the first insulating area 37 is inconspicuous. Therefore, it is possible for the wristwatch 1 to be formed as the equipment provided with the photoelectric conversion module 14 having the first insulating area 37 which is inconspicuous.

(8) According to the present embodiment, the silicon wafer 65 including silicon is used in the method of manufacturing the photoelectric conversion device 24. Further, the silicon wafer 65 is provided with the recessed parts 70 which are arranged at predetermined intervals, and are formed from the second surface 65a side. Subsequently, silicon in the recessed parts 70 is thermally oxidized. By thermally oxidizing the silicon wafer 65, there is formed the first insulating area 37 including the Si oxide in the shape having the circular rings connected to each other in a row.

The areas located across the first insulating areas 37 are defined as the first photoelectric conversion area 29 and the second photoelectric conversion area 30. The n+ impurity area 48 and the p+ impurity area 47 are formed in the first photoelectric conversion area 29. The n+ impurity area 48 and the p+ impurity area 47 are also formed in the second photoelectric conversion area 30. The n+ impurity area 48 and the p+ impurity area 47 are made different in conductivity type from each other.

There are disposed the positive electrode 45, the negative electrode 46, and the coupling interconnection 52 for electrically coupling the n+ impurity area 48 disposed in the first photoelectric conversion area 29 and the p+ impurity area 47 disposed in the second photoelectric conversion area 30 to each other. The coupling interconnection 52 is disposed so as to pass above the first insulating area 37. The n+ impurity area 48 and the p+ impurity area 47 are different in polarity from each other. Therefore, the n+ impurity area 48 and the p+ impurity area 47 are electrically coupled in series to each other.

The surface at the opposite side to the second surface 65a of the silicon wafer 65 is defined as the first surface 65b. The first surface 65b is ground to expose the second insulating film 50 of the first insulating area 37 as the Si oxide on the first surface 65b. Since the first insulating area 37 is disposed from the second surface 65a of the silicon wafer 65 to the first surface 65b due to this process, the first photoelectric conversion area 29 and the second photoelectric conversion area 30 are electrically isolated from each other.

Further, by using the photolithography method, it is possible to finely form the recessed parts 70. Further, by thermally oxidizing the silicon wafer 65, it is possible to form the second insulating film 50 made of the Si oxide in the recessed parts 70. It is possible to set the film thickness of the second insulating film 50 to several micrometers. The width of the first insulating area 37 when viewed from the thickness direction of the silicon wafer 65 becomes the length obtained by adding the width of the recessed part 70 and the film thickness of the second insulating film 50 on the side surface of the recessed part 70 to each other. Therefore, the width of the first insulating area 37 becomes no larger than several tens of micrometers.

By cutting the silicon wafer 65 to separate the first photoelectric conversion area 29 and the second photoelectric conversion area 30 from each other, and then disposing the insulator between the first photoelectric conversion area 29 and the second photoelectric conversion area 30, it is possible to electrically separate the first photoelectric conversion area 29 and the second photoelectric conversion area 30 from each other. On this occasion, the distance between the first photoelectric conversion area 29 and the second photoelectric conversion area 30 becomes several millimeters. Compared to the photoelectric conversion device in which the first photoelectric conversion area 29 and the second photoelectric conversion area 30 are separated from each other, and the insulator is disposed therebetween, it is possible for the photoelectric conversion device 24 according to the present embodiment to shorten the width of the first insulating area 37. Therefore, it is possible for the photoelectric conversion device 24 to shorten the width of the insulating area between the first photoelectric conversion area 29 and the second photoelectric conversion area 30. In other words, it is possible to shorten the width of the first insulating area 37 located between the photoelectric conversion areas 28 adjacent to each other.

### Second Embodiment

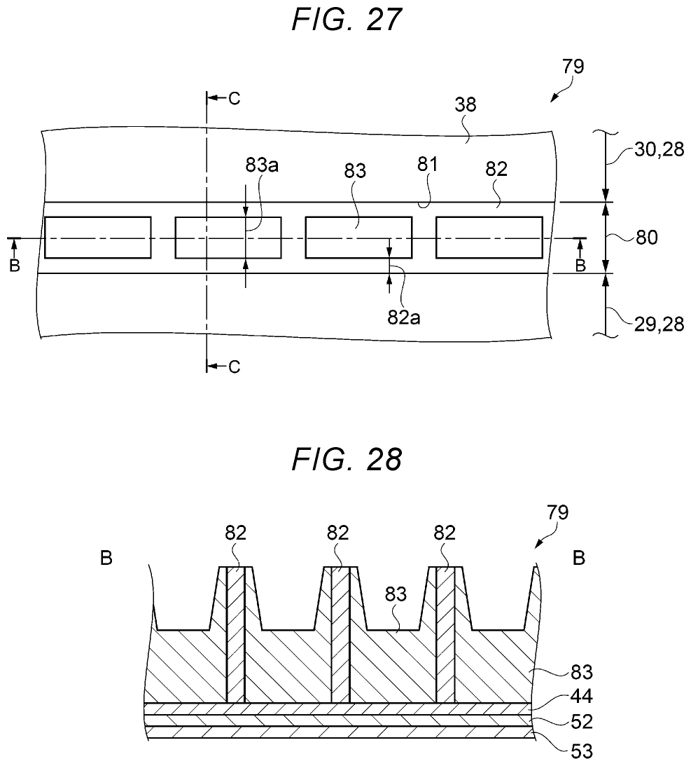

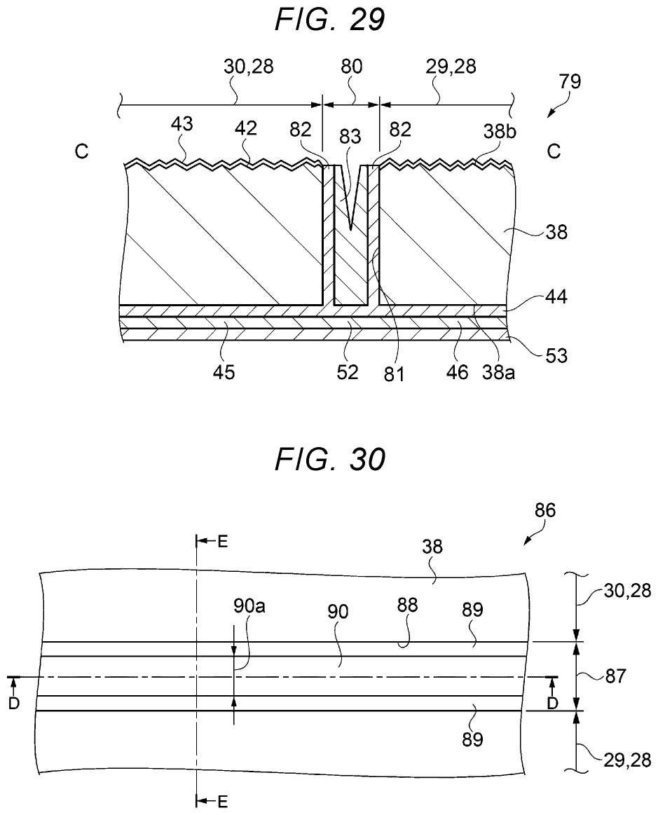

Then, a photoelectric conversion device according to another embodiment will be described using FIG. 27 through FIG. 29. FIG. 27 is a schematic plan view for explaining an insulating area. FIG. 28 and FIG. 29 are schematic side cross-sectional views for explaining the insulating area. FIG. 28 is a diagram of the photoelectric conversion device viewed from a plane along the line BB in FIG. 27. FIG. 29 is a diagram of the photoelectric conversion device viewed from a plane along the line CC in FIG. 27. The present embodiment is different from the first embodiment in the point that the shape of the first insulating area 37 when viewing the photoelectric conversion device 24 from the thickness direction is different. It should be noted that the description of the same point as in the first embodiment will be omitted.

In other words, in the present embodiment, as shown in FIG. 27 through FIG. 29, a photoelectric conversion device 79 is provided with the semiconductor substrate 38. In the semiconductor substrate 38, there is disposed a second insulating area 80 as an insulating area sandwiched between the first photoelectric conversion area 29 and the second photoelectric conversion area 30. In the semiconductor substrate 38, there is formed an eleventh hole 81. Inside the eleventh hole 81, there is disposed a sixth insulating film 82. The sixth insulating film 82 is a film corresponding to the second insulating film 50 in the first embodiment. The sixth insulating film 82 has a shape having quadrangular frame-like shapes arranged in a row.

Inside each part having the quadrangular frame-like shape of the sixth insulating film 82, there is disposed a second reinforcing part 83 as an Si compound. The second reinforcing part 83 has a prismatic columnar shape, and on the first surface 38b side, the center of the second reinforcing part 83 is recessed. The width of the second reinforcing part 83 when viewed from the thickness direction of the semiconductor substrate 38 is defined as a second reinforcing part width 83a. It is preferable for the second reinforcing part width 83a to be no smaller than 6 μm and no larger than 16 μm. When the second reinforcing part width 83a is smaller than 6 μm, it becomes difficult to dispose the material of the second reinforcing part 83 inside the sixth insulating film 82. Further, when the second reinforcing part width 83a is larger than 16 μm, the width of the second insulating area 80 becomes large, and therefore, the proportion of the area occupied by the photoelectric conversion areas 28 in the photoelectric conversion device 79 becomes small, and thus, the power generation efficiency becomes low.

The width of the quadrangular frame of the sixth insulating film 82 is defined as a sixth insulating film width 82a. It is preferable for the sixth insulating film width 82a to be no smaller than 1 μm and no larger than 5 μm. The sixth insulating film width 82a represents an average value of widths of a number of frames formed. The quadrangular frame part is formed by thermally oxidizing a recessed part provided to the semiconductor substrate 38 including silicon. The distance between the second reinforcing parts 83 adjacent to each other when the quadrangular frames are connected to each other in a row is no smaller than 2 μm which is twice as large as the sixth insulating film width 82a. Since the width of the quadrangular frame is made substantially twice due to the thermal oxidation, the recessed parts are formed in the process prior to the thermal oxidation so that the distance between the side surfaces of the recessed parts is no smaller than 1 μm. When the distance between the side surfaces of the recessed parts becomes smaller than 1 μm, there arises a possibility that the recessed parts adjacent to each other merge with each other to fail to form the quadrangular frames due to a variation when processing the recessed parts. By making the distance between the side surfaces of the recessed parts no smaller than 1 μm, it is possible to form the quadrangular frames connected to each other in a row with high quality. Therefore, it is preferable for the sixth insulating film width 82a to be no smaller than 1 μm. Further, when the sixth insulating film width 82a exceeds 5 μm, the time for which the silicon is oxidized is elongated. By making the sixth insulating film width 82a no larger than 5 μm, it is possible to form the sixth insulating film 82 with high productivity.

### Third Embodiment

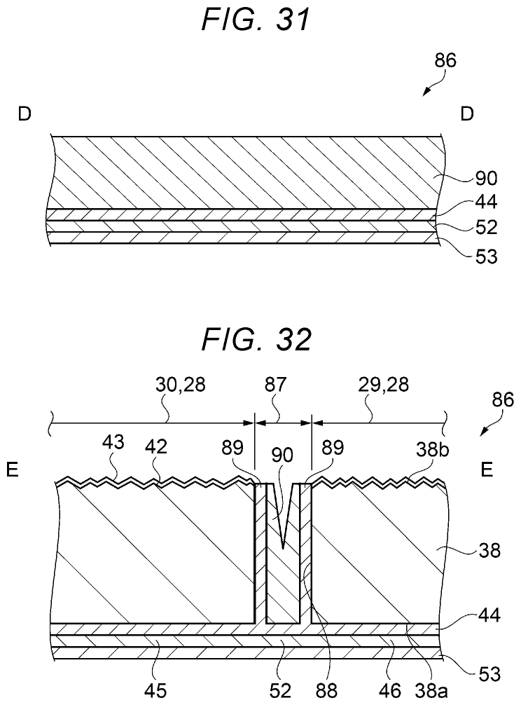

Then, a photoelectric conversion device according to another embodiment will be described using FIG. 30 through FIG. 32. FIG. 30 is a schematic plan view for explaining an insulating area. FIG. 31 and FIG. 32 are schematic side cross-sectional views for explaining the insulating area. FIG. 31 is a diagram of the photoelectric conversion device viewed from a plane along the line DD in FIG. 30. FIG. 32 is a diagram of the photoelectric conversion device viewed from a plane along the line EE in FIG. 30. The present embodiment is different from the first embodiment in the point that the shape of the first insulating area 37 when viewing the photoelectric conversion device 24 from the thickness direction is different. It should be noted that the description of the same point as in the first embodiment and the second embodiment will be omitted.

In other words, in the present embodiment, as shown in FIG. 30 through FIG. 32, a photoelectric conversion device 86 is provided with the semiconductor substrate 38. In the semiconductor substrate 38, there is disposed a third insulating area 87 as an insulating area sandwiched between the first photoelectric conversion area 29 and the second photoelectric conversion area 30. In the semiconductor substrate 38, there is formed a second groove 88. Inside the second groove 88, there are disposed seventh insulating films 89. The seventh insulating films 89 are each a film corresponding to the second insulating film 50 in the first embodiment. The seventh insulating films 89 each have a shape extending along a side surface of the second groove 88. The second groove 88 has two side surfaces opposed to each other. The seventh insulating films 89 are respectively disposed on the two side surfaces.

Inside the two seventh insulating films 89 opposed to each other, there is disposed a third reinforcing part 90 as an Si compound. The third reinforcing part 90 extends along the seventh insulating films 89, and on the first surface 38b side, the center of the third reinforcing part 90 is recessed. The width of the third reinforcing part 90 when viewed from the thickness direction of the semiconductor substrate 38 is defined as a third reinforcing part width 90a. It is preferable for the third reinforcing part width 90a to be no smaller than 6 μm and no larger than 16 μm. When the third reinforcing part width 90a is smaller than 6 μm, it becomes difficult to dispose the material of the third reinforcing part 90 inside the seventh insulating films 89. Further, when the third reinforcing part width 90a is larger than 16 μm, the width of the third insulating area 87 becomes large, and therefore, the proportion of the area occupied by the photoelectric conversion areas 28 in the photoelectric conversion device 86 becomes small, and thus, the power generation efficiency becomes low.

It should be noted that the present embodiment is not limited to the embodiment described above, but a variety of modifications or improvements can also be added by those skilled in the art within the technical concept of the present disclosure. Some modified examples will be described below.

### MODIFIED EXAMPLE 1

In the first embodiment, the circular shape is adopted as the shape of the photoelectric conversion device 24. It is also possible for the shape of the photoelectric conversion device 24 to be a polygonal shape such as a triangular shape or a quadrangular shape. Besides the above, as the shape of the photoelectric conversion device 24, it is also possible to adopt a shape constituted by a plurality of curved lines such as an elliptical shape. It is possible to dispose the photoelectric conversion device 24 in accordance with the shape of an electronic apparatus in which the photoelectric conversion device 24 is to be disposed.

### MODIFIED EXAMPLE 2

In the first embodiment described above, the first photoelectric conversion area 29 through the eighth photoelectric conversion area 36 are provided with the shapes substantially the same in area. The first photoelectric conversion area 29 through the eighth photoelectric conversion area 36 can also be different in area from each other. It is possible to make it easy to dispose the photoelectric conversion device 24 in accordance with the shape of an electronic apparatus in which the photoelectric conversion device 24 is to be disposed.

### MODIFIED EXAMPLE 3

In the first embodiment described above, the first photoelectric conversion area 29 through the eighth photoelectric conversion area 36 are electrically coupled in series to each other. It is also possible to electrically couple the first photoelectric conversion area 29 through the eighth photoelectric conversion area 36 in parallel to each other. Further, it is also possible to electrically couple some of the first photoelectric conversion area 29 through the eighth photoelectric conversion area 36 in series to each other, and some of them in parallel to each other. By changing the configuration of the electric circuit, it is possible to output a predetermined voltage.

### MODIFIED EXAMPLE 4

In the first embodiment described above, the wristwatch 1 is equipped with the direction sensor 17. Besides the direction sensor 17, the wristwatch 1 can also be provided with a pressure sensor, an acceleration sensor, an angular velocity sensor, and a temperature sensor, and in addition, an infrared sensor for detecting a blood flow. The acceleration sensor and the angular velocity sensor detect a motion of an arm of the operator. The temperature sensor detects the ambient temperature. The infrared sensor detects the pulse of the operator. Further, it is possible to make the wristwatch 1 multifunction.

### MODIFIED EXAMPLE 5

In the first embodiment described above, the wristwatch 1 is shown as an example of an electronic apparatus equipped with the photoelectric conversion module 14. It is also possible to install the photoelectric conversion module 14 in other electronic apparatuses. It is also possible to install the photoelectric conversion module 14 in a variety of electronic apparatuses such as a flashlight, a portable blood pressure meter, a radio, a smartphone, a telephone, and a hearing aid.

### MODIFIED EXAMPLE 6

In the first embodiment described above, the texture formation process in the step S6 is performed after the diode formation process in the step S4 and the interconnection formation process in the step S5. It is also possible to perform the texture formation process in the step S6 between the insulating area formation process in the step S3 and the diode formation process in the step S4. Besides the above, it is also possible to perform the texture formation process in the step S6 between the diode formation process in the step S4 and the interconnection formation process in the step S5. It is also possible to change the order of the processes in accordance with the arrangement of the manufacturing apparatuses.

### MODIFIED EXAMPLE 7

In the first embodiment described above, the second insulating film 50 is shaped like the circular ring. The shape of the second insulating film 50 can be an elliptical ring shape, or can also be a polygonal ring shape. Besides the above, it is also possible to adopt a ring shaped like a contour of a symbol or a character. It is also possible to change the shape of the second insulating film 50 in accordance with an appearance design. It is possible to improve the appearance.

Hereinafter, the contents derived from the embodiments will be described.

The photoelectric conversion device according to the present disclosure includes a semiconductor substrate including silicon, wherein the semiconductor substrate includes a first photoelectric conversion area and a second photoelectric conversion area which are disposed on the semiconductor substrate, and receive light to perform a photoelectric conversion, and an insulating area which is disposed between the first photoelectric conversion area and the second photoelectric conversion, and includes an Si oxide.

According to this configuration, the photoelectric conversion device is provided with the semiconductor substrate. Further, the semiconductor substrate has the first photoelectric conversion area, the second photoelectric conversion area, and the insulating area. The first photoelectric conversion area and the second photoelectric conversion area each receive the light to convert the optical energy into the electrical energy. The insulating area is disposed between the first photoelectric conversion area and the second photoelectric conversion area. Further, the insulating area electrically separates the first photoelectric conversion area and the second photoelectric conversion area from each other. Therefore, each of the first photoelectric conversion area and the second photoelectric conversion area individually generates power.

The semiconductor substrate includes silicon, and the insulating area includes the Si oxide. Since the Si oxide is an insulator, it is possible for the insulating area to electrically separate the first photoelectric conversion area and the second photoelectric conversion area from each other. Further, the insulating area can be formed by providing the recessed parts to the semiconductor substrate, and then thermally oxidizing the recessed parts.

By using the photolithography method, it is possible to finely form the recessed parts. Further, by thermally oxidizing the semiconductor substrate, it is possible to form the film of the Si oxide in each of the recessed parts. It is possible to set the film thickness of the Si oxide to several micrometers. The width of the insulating area when viewed from the thickness direction of the semiconductor substrate becomes the length obtained by adding the width of the recessed part and the film thickness of the Si oxide on the side surface of the recessed part to each other. Therefore, the width of the insulating area becomes no larger than several tens of micrometers.

By cutting the semiconductor substrate to separate the first photoelectric conversion area and the second photoelectric conversion area from each other, and then disposing the insulator between the first photoelectric conversion area and the second photoelectric conversion area, it is possible to electrically separate the first photoelectric conversion area and the second photoelectric conversion area from each other. On this occasion, the distance between the first photoelectric conversion area and the second photoelectric conversion area becomes several millimeters. Compared to the photoelectric conversion device in which the first photoelectric conversion area and the second photoelectric conversion area are separated from each other, and the insulator is disposed therebetween, it is possible for the photoelectric conversion device described in the embodiments to shorten the width of the insulating area. Therefore, it is possible for the photoelectric conversion device to shorten the width of the insulating area between the first photoelectric conversion area and the second photoelectric conversion area. Thus, it is possible to obtain the photoelectric conversion device in which a certain distance is not provided between the first photoelectric conversion area and the second photoelectric conversion area in order to electrically separate the first photoelectric conversion area and the second photoelectric conversion area from each other, and thus the area of the photoelectric conversion area is not reduced.

In the photoelectric conversion device described above, the insulating area may include an Si nitride surrounded by the Si oxide.

According to this configuration, the insulating area includes the Si nitride. The insulating area is formed by thermally oxidizing the recessed parts. When arranging the recessed parts at predetermined intervals, since the strength of the plane along the arrangement decreases, the semiconductor substrate becomes easy to break. By disposing the Si nitride in the recessed parts, the strength of the plane along the arrangement increases, and therefore, it is possible to make the semiconductor substrate difficult to break.

In the photoelectric conversion device described above, the width of the Si oxide may be no smaller than 1 μm and no larger than 5 μm.

According to this configuration, the width of the Si oxide is made no smaller than 1 μm and no larger than 5 μm. The width of the Si oxide represents an average value of a number of the Si oxides formed. The Si oxide is formed by thermally oxidizing the recessed part provided to the semiconductor substrate including silicon. When the Si oxides are connected to each other in a row, the distance between the Si oxides adjacent to each other is no smaller than 2 μm. Since the width of the Si oxide is made substantially twice due to the thermal oxidation, the recessed parts are formed in the process prior to the thermal oxidation so that the distance between the side surfaces of the recessed parts is no smaller than 1 μm. When the distance between the side surfaces of the recessed parts becomes smaller than 1 μm, there arises a possibility that the recessed parts adjacent to each other merge with each other to fail to appropriately form the Si oxides due to a variation when processing the recessed parts. By making the width of the Si oxide no smaller than 1 μm, it is possible to form the Si oxides connected to each other in a row with high quality. When the width of the Si oxide exceeds 5 μm, the time for which the silicon is oxidized is elongated. By making the width of the Si oxide no larger than 5 μm, it is possible to form the Si oxides with high productivity.

In the photoelectric conversion device described above, a first impurity area of a first conductivity type and a second impurity area of a second conductivity type different from the first impurity area disposed in the first photoelectric conversion area and the second photoelectric conversion area, and an interconnection configured to electrically couple the first impurity area disposed in the first photoelectric conversion area and the second impurity area disposed in the second photoelectric conversion area to each other may be provided to a second surface at an opposite side to a first surface with which the semiconductor substrate receives the light, and the interconnection may be disposed so as to pass above the insulating area.

According to this configuration, the first impurity area of the first conductivity type and the second impurity area of the second conductivity type are disposed in the first photoelectric conversion area. The first impurity area and the second impurity area are also disposed in the second photoelectric conversion area. Further, the interconnection electrically couples the first impurity area disposed in the first photoelectric conversion area and the second impurity area disposed in the second photoelectric conversion area to each other. The first photoelectric conversion area and the second photoelectric conversion area are coupled in series to each other by the interconnection. Further, the interconnection is disposed on the semiconductor substrate. Therefore, it is possible for the photoelectric conversion device to output a voltage obtained by adding a voltage output by the first impurity area and a voltage output by the second impurity area to each other.

The photoelectric conversion module includes the photoelectric conversion device described above, and a wiring board electrically coupled to the photoelectric conversion device.

According to this configuration, the photoelectric conversion module is provided with the photoelectric conversion device and the wiring board. Further, it is possible for the photoelectric conversion device to shorten the width of the insulating area. Therefore, in the photoelectric conversion module, since the area of the insulating area is small, it is possible to increase the proportion of the area occupied by the first photoelectric conversion area and the second photoelectric conversion area.

The electronic apparatus includes the photoelectric conversion module described above.

According to this configuration, the electronic apparatus is provided with the photoelectric conversion module described above. Further, the photoelectric conversion module described above is provided with the photoelectric conversion device, and the photoelectric conversion device is capable of shortening the width of the insulating area. Therefore, it is possible for the electronic apparatus to be made as an apparatus equipped with the photoelectric conversion module capable of reducing the area of the insulating area to increase the proportion of the area occupied by the first photoelectric conversion area and the second photoelectric conversion area.

The method of manufacturing a photoelectric conversion device includes forming recessed parts arranged at predetermined intervals on a second surface opposite to a first surface on which light is received in a semiconductor substrate including silicon, forming an insulating area including an Si oxide in a shape having circular rings connected to each other in a row by thermally oxidizing silicon in the recessed parts, forming a first impurity area of a first conductivity type and a second impurity area of a second conductivity type different from the first impurity area in each of a first photoelectric conversion area and a second photoelectric conversion area located across the insulating area, disposing an interconnection configured to electrically couple the first impurity area disposed in the first photoelectric conversion area and the second impurity area disposed in the second photoelectric conversion area to each other so as to pass above the insulating area, and grinding the first surface of the semiconductor substrate to expose the Si oxide.

According to this configuration, in the method of manufacturing the photoelectric conversion device, there is used the semiconductor substrate including silicon. Further, the recessed parts arranged at predetermined intervals are provided to the semiconductor substrate formed from the first surface side. Subsequently, silicon in the recessed parts is thermally oxidized. By thermally oxidizing the semiconductor substrate, there is formed the insulating area including the Si oxide in the shape having the circular rings connected to each other in a row.

The areas located across the insulating area are defined as the first photoelectric conversion area and the second photoelectric conversion area, respectively. The first impurity area of the first conductivity type and the second impurity area of the second conductivity type are formed in the first photoelectric conversion area. The first impurity area and the second impurity area are also formed in the second photoelectric conversion area. The first impurity area of the first conductivity type and the second impurity area of the second conductivity type are made different in conductivity type from each other.

The interconnection for electrically coupling the first impurity area disposed in the first photoelectric conversion area and the second impurity area disposed in the second photoelectric conversion area to each other is disposed. The interconnection is disposed so as to pass above the insulating area. The first impurity area and the second impurity area are different in polarity from each other. Therefore, the first photoelectric conversion area and the second photoelectric conversion area are electrically coupled in series to each other.

The first surface of the semiconductor substrate is ground to expose the Si oxide on the first surface. According to this process, since the Si oxide is disposed from the first surface to the second surface of the semiconductor substrate, the first photoelectric conversion area and the second photoelectric conversion area are electrically isolated from each other.

Further, by using the photolithography method, it is possible to finely form the recessed parts. Further, by thermally oxidizing the semiconductor substrate, it is possible to form the film of the Si oxide in each of the recessed parts. It is possible to set the film thickness of the Si oxide to several micrometers. The width of the insulating area when viewed from the thickness direction of the semiconductor substrate becomes the length obtained by adding the width of the recessed part and the film thickness of the Si oxide on the side surfaces opposed to each other of the recessed part to each other. Therefore, the width of the insulating area becomes no larger than several tens of micrometers.

By cutting the semiconductor substrate to separate the first photoelectric conversion area and the second photoelectric conversion area from each other, and then disposing the insulator between the first photoelectric conversion area and the second photoelectric conversion area, it is possible to electrically separate the first photoelectric conversion area and the second photoelectric conversion area from each other. On this occasion, the distance between the first photoelectric conversion area and the second photoelectric conversion area becomes several millimeters. Compared to the photoelectric conversion device in which the first photoelectric conversion area and the second photoelectric conversion area are separated from each other, and the insulator is disposed therebetween, it is possible for the photoelectric conversion device described in the embodiments to shorten the width of the insulating area. Therefore, it is possible for the photoelectric conversion device to shorten the width of the insulating area between the first photoelectric conversion area and the second photoelectric conversion area. Further, it is possible to increase the area of the photoelectric conversion area.

In the photoelectric conversion device described above, it is preferable for the shape of the Si oxide when viewed from the thickness direction of the semiconductor substrate in the insulating area to be a shape having circular rings arranged in a row.

According to this configuration, when viewed from the thickness direction of the semiconductor substrate, the shape of the Si oxide in the insulating area is the shape having circular rings arranged in a row. By forming the recessed parts each having a circular shape at regular intervals and then thermally oxidizing the semiconductor substrate, it is possible to easily form the insulating area to have the shape having the circular rings arranged in a row. Therefore, it is possible to form the insulating area using a simple method.

What is claimed is:

1. A photoelectric conversion device comprising:
a semiconductor substrate including silicon, wherein
the semiconductor substrate includes
a first photoelectric conversion area and a second photoelectric conversion area that receive light to perform a photoelectric conversion, and
an insulating area that is disposed between the first photoelectric conversion area and the second photoelectric conversion area, and that includes an Si oxide.

2. The photoelectric conversion device according to claim 1, wherein
the insulating area includes an Si nitride surrounded by the Si oxide.

3. The photoelectric conversion device according to claim 2, wherein
the width of the Si oxide is no smaller than 1 μm and no larger than 5 μm.

4. The photoelectric conversion device according to claim 1, further comprising:
an interconnection configured to electrically couple a first impurity area of a first conductivity type disposed in the first photoelectric conversion area and a second impurity area of a second conductivity type disposed in the second photoelectric conversion area, the interconnection being provided on a second surface of the semiconductor substrate at an opposite side to a first surface of the semiconductor substrate that receives the light, and
the interconnection overlapping to the insulating area.

5. A photoelectric conversion module comprising:
the photoelectric conversion device according to claim 1; and
a wiring board electrically coupled to the photoelectric conversion device.

6. An electronic apparatus comprising:
the photoelectric conversion module according to claim 5.

7. A method of manufacturing a photoelectric conversion device, the method comprising:
forming recessed parts arranged at predetermined intervals from a second surface of the semiconductor substrate at an opposite side to a first surface of the semiconductor substrate that receives light, the semiconductor substrate including silicon;
forming an insulating area including an Si oxide in a shape having circular rings connected in a row by thermally oxidizing silicon of a surface of the recessed parts;
forming a first impurity area of a first conductivity type and a second impurity area of a second conductivity type different from the first impurity type in each of a first photoelectric conversion area and a second photoelectric conversion area, the insulating area being disposed between the first photoelectric conversion area and the second photoelectric conversion area;
disposing an interconnection configured to electrically couple the first impurity area disposed in the first photoelectric conversion area and the second impurity area disposed in the second photoelectric conversion area, the interconnection overlapping to the insulating area; and
grinding the first surface of the semiconductor substrate to expose the Si oxide.
